(19) United States
(12) Patent Application Publication
(10) Pub. No.: US 2026/0267755 A1
(43) Pub. Date: Sep. 10, 2026

(54) DEVICE HAVING DIGITAL/ANALOG CONVERSION CIRCUIT

(71) Applicant: Hitachi High-Tech Corporation, Tokyo (JP)

(72) Inventors: Wen LI, Tokyo (JP); Shinichi MURAKAMI, Tokyo (JP); Naoya ISHIGAKI, Tokyo (JP); Hiroyuki TAKAHASHI, Tokyo (JP); Makoto SUZUKI, Tokyo (JP)

(21) Appl. No.: 19/166,131

(22) PCT Filed: Jun. 23, 2023
(86) PCT No.: PCT/JP2023/023294

§ 371 Date: Sep. 17, 2025

(51) Int. Cl. G06F 11/263

(52) U.S. Cl. CPC G06F 11/263

(57) ABSTRACT

A device including a DA conversion circuit includes at least: a processor 10P that outputs a DA conversion target value, a pre-stage circuit that receives the DA conversion target value from the processor, corrects the DA conversion target value according to correction data, and outputs the corrected DA conversion target value, a body circuit including one or more correction target DA converter elements and that performs DA conversion on the corrected DA conversion target value, and an AD converter. Here, the correction target DA converter element is a hybrid-type DA converter element that outputs, from an output terminal, an analog value obtained by adding an analog value output by a first type circuit segment in charge of an upper order and an analog value output by a second type circuit segment in charge of a lower order.

### TECHNICAL FIELD

The present invention relates to a device having a digital/analog conversion circuit (hereinafter, also referred to as a DA conversion circuit or a DA converter element), for example, a device having a DA conversion circuit capable of achieving high accuracy.

### BACKGROUND ART

A technique for providing a highly accurate DA conversion circuit is described in, for example, PTL 1. PTL 1 discloses a technique for improving the accuracy of a DA conversion circuit using an R-2R resistor DAC (digital and analog converter) element, an interpolation DAC element, and a sigma-delta modulator element. In PTL 1, a calibration process (corresponding to a calibration test in an embodiment to be described later) is performed for high accuracy.

### CITATION LIST

### Patent Literature

PTL 1: JP2022-3830A

### SUMMARY OF INVENTION

### Technical Problem

As a result of studies by the present inventor, it is found that the technique disclosed in PTL 1 has at least one of the following improvements.

It is expected that conversion characteristics of a DA converter may change due to a dynamic change in a temperature (environmental temperature) of a device including a DA converter element (hereinafter, also simply referred to as the DA converter). Therefore, it is necessary to repeatedly perform a calibration test, whereas the technique disclosed in PTL 1 has room for improvement in a calibration test time.

A target device to which an analog value output from the DA converter is supplied includes a device that requires a high voltage or a high current. In such a device, it is difficult to supply an output of the DA converter as it is to the target device, and an amplifier circuit is generally connected between the DA converter and the target device. In the amplifier circuit, an input and output characteristic represented by, for example, an amplification factor fluctuates due to, for example, a change in temperature (environmental temperature), and accordingly fluctuates over time. As a result, the analog value supplied to the target device also fluctuates with time. In the technique described in PTL 1, there is room for improvement in such a point.

An object of the invention is to provide a device that solves the one or more problems.

Other objects and novel characteristics of the invention will become apparent from description of the present description and the accompanying drawings.

### Solution to Problem

An overview of a representative embodiment disclosed in the present application will be briefly described as follows.

That is, a device according to the embodiment includes at least: a processor configured to output a DA conversion target value; a pre-stage circuit configured to receive the DA conversion target value from the processor, correct the DA conversion target value according to correction data, and output the corrected DA conversion target value; a body circuit including one or more correction target DA converter elements and that performs DA conversion on the corrected DA conversion target value; and an AD converter. Here, the correction target DA converter element is a hybrid-type DA converter element that outputs, from an output terminal, an analog value obtained by adding an analog value output by a first type circuit segment in charge of an upper order and an analog value output by a second type circuit segment in charge of a lower order. In addition, as a calibration test for creating or updating correction data, the processor: (A) acquires a plurality of test pairs each of which is a pair of a test input value and a test result value having the following characteristics: (A1) the test input value is a value input to the body circuit as a DA conversion target value with or without correction, (A2) the test result value is a value obtained by performing AD conversion, by the AD converter, on an analog value output by inputting the test input value to the body circuit, and (B) updates the correction data based on the plurality of test pairs in (A). The number of the test pairs acquired during a calibration test period is smaller than 2N, and the N is the number of bits indicating a resolution of the correction target DA converter element.

A device according to another embodiment includes at least a body circuit including one or more DA converter elements configured to convert a body input bit string, which is a received bit string, into a body output analog value, which is an analog value, and output the body output analog value; a processor configured to output a processor output bit string; a pre-stage circuit configured to receive the processor output bit string and outputs the body input bit string; and an AD converter. Here, the pre-stage circuit corrects the processor output bit string based on correction data and outputs the body input bit string, the body circuit includes an amplifier circuit that amplifies an analog value output by the DA converter element and outputs the amplified analog value as the body output analog value. The processor (A) acquires a plurality of pairs of a test bit string and a test result bit string having the following characteristics: (A1) the test bit string is the processor output bit string or the body input bit string for a calibration test, (A2) the test result bit string is acquired by converting the body output analog value by the AD converter, and (B) updates the correction data based on the plurality of pairs in (A).

### Advantageous Effects of Invention

To briefly describe the effects obtained by the typical embodiments among the inventions disclosed in the present application, it is possible to provide a device including a highly accurate DA conversion circuit.

### BRIEF DESCRIPTION OF DRAWINGS

FIG. 1 is a block diagram showing a configuration of a device having a DA converter according to Embodiment 1.

FIG. 2 is a block diagram showing a configuration of the DA converter according to Embodiment 1.

FIG. 3 is a circuit diagram showing the configuration of the DA converter according to Embodiment 1.

FIG. 4 is a flowchart when the DA converter according to Embodiment 1 is operated.

FIG. 5 is a flowchart showing a calibration test according to Embodiment 1.

FIG. 6 is a diagram showing the calibration test according to Embodiment 1.

FIG. 7 is a diagram showing a correction amount according to Embodiment 1.

FIG. 8 is a block diagram showing a configuration of a bit string correction circuit according to Embodiment 1.

FIG. 9 is a block diagram showing a configuration of a DA converter according to Embodiment 2.

FIG. 10 is a diagram showing a bit string correction circuit according to Embodiment 2.

FIG. 11 is a block diagram showing a configuration of a charged particle beam device according to Embodiment 4.

FIG. 12 is a diagram showing equations illustrating the embodiment.

FIG. 13 is a block diagram showing a configuration of a DA converter according to a modification of Embodiment 2.

### DESCRIPTION OF EMBODIMENTS

Embodiments will be described with reference to the drawings. The embodiments described below do not limit the invention according to the range of claims, and it is not necessary that all of the elements and combinations described in the embodiments are essential to the solution of the invention.

### Embodiment 1

### <Configuration of Device>

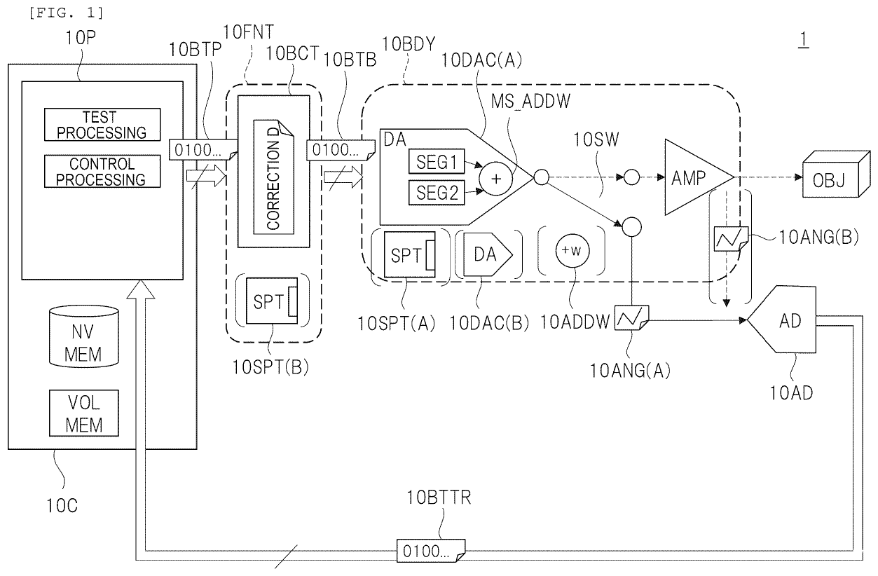

FIG. 1 is a block diagram showing a configuration of a device according to Embodiment 1. In FIG. 1, reference numeral 1 denotes a device. The device 1 includes a processor 10P, a pre-stage circuit 10FNT, a body circuit 10BDY, and an analog/digital converter (hereinafter, referred to as an AD converter) 10AD.

In FIG. 1, OBJ indicates a target device, and an analog value is output from the device 1 to the target device OBJ. Here, a case in which the target device OBJ is provided outside the device 1 will be described, and of course, the target device OBJ may be included in the device 1. The target device OBJ is a device that operates by receiving an analog value from the device 1. An example of the target device OBJ will be described later, and the invention is not limited thereto. In a broad sense, the target device OBJ can be regarded as a control target device whose operation is controlled by an analog value from the device 1, and the target device OBJ may be regarded as an amplifier circuit such as an operational amplifier. In the present specification, a value indicated by an analog method (at least indicating a value by a continuously changing (or allowing) a physical quantity such as a voltage or a current) is referred to as an analog value. Processing such as generation, output, input, and transmission and reception of an analog value of a physical entity (an element, a circuit, or a device) actually means at least changing a physical quantity that continuously changes (or causes to change) such as a current or a voltage.

In the following description, the pre-stage circuit 10FNT and the body circuit 10BDY shown in FIG. 1 may be collectively referred to as a DA conversion circuit.

### <<Processor>>

The processor 10P is a device that performs predetermined processing (control processing in FIG. 1) to generate a value (hereinafter, may be referred to as a DA conversion target value) to be given to the target device OBJ after DA conversion via a circuit to be described later as a digital value (bit string) and transmits the digital value. In the following description, the bit string generated and transmitted by the processor 10P as a result of the control processing is referred to as a processor output bit string, and is exemplified as 10BTP in FIG. 1.

The processor 10P is, for example, a device that performs predetermined processing by executing a program such as a CPU or a GPU. However, the processor 10P may be an FPGA or another IC as long as the digital value (bit string) can be generated by performing the predetermined processing. The processor 10P may be a part of a component 10C such as a motherboard or a controller together with a volatile memory VOLMEM or a nonvolatile memory NVMEM (a flash memory or an HDD is an example), or may be a computer. In addition, the device 1 itself may be a computer. A program (group) for implementing test processing and control processing executed by the processor 10P is stored in the nonvolatile memory NVMEM.

### <<Body Circuit and Pre-Stage Circuit>>

The body circuit 10BDY is a circuit including one or more DA converters (correction target DA converters) 10DAC that convert a body input bit string 10BTB into a body output analog value 10ANG(A) that is an analog value and output the body output analog value 10ANG(A). It can be said that the value of the body input bit string 10BTB output according to the processor output bit string 10BTP having the DA conversion target value has a “corrected DA conversion target value”.

The pre-stage circuit 10FNT is a circuit that receives the processor output bit string 10BTP and outputs the body input bit string 10BTB. The pre-stage circuit 10FNT includes a bit string correction circuit 10BCT that corrects the processor output bit string 10BTP based on correction data (correction D in FIG. 1) and outputs the body input bit string 10BTB. The correction data is stored in a memory (not shown) in a pre-stage circuit. The correction may not always be performed. For example, the correction is performed after a calibration test described later.

### <<AD Converter>>

The AD converter 10AD is an element to be used during the calibration test to be described later. During the calibration test, the AD converter 10AD converts the body output analog value 10ANG into a bit string 10BTTR. In the following description, the bit string 10BTTR is referred to as a test result bit string 10BTTR for easy distinction. In the following description, the calibration test may be simply referred to as a test. Of course, the AD converter 10AD may be used for applications other than the test.

### <<Test Object and Correction Purpose>>

The calibration test processing is processing performed by the processor 10P, and the calibration test is performed to grasp a conversion relation (mainly a relation of DA conversion) between an input and an output of the body circuit 10BDY due to a characteristic change (for example, an environmental factor such as a temperature) of the body circuit 10BDY. Correction data to be used in the pre-stage circuit 10FNT is generated based on a result of the test processing. Although a characteristic change in interest in Embodiment 1 is the DA converter 10DAC(A), characteristic changes s in other elements may also be considered. For example, a characteristic change in the amplifier circuit AMP described later may also be considered.

A typical purpose of correction performed by grasping the conversion relation is to improve digital and analog linearity. A 3-bit bit string (an offset binary format or an uncoded binary format) will be described as an example. If a current output for a bit string (1, 0, 0) represented in the order MSB, intermediate bit, LSB is 4 mA, in the case of a DA converter having high linearity, in view of the meaning of each bit, the analog value output for the bit string (0, 1, 0) is ideally 2 mA, and the analog value output for the bit string (0, 0, 1) is ideally 1 mA.

However, when the characteristic change in the circuit in charge of the intermediate bit in the DA converter is significant, and 3 mA is output only for the bit string (0, 1, 0), while other outputs do not change, the linearity described above decreases. The correction performed by the pre-stage circuit 10FNT improves the decreased linearity by actually changing the bit string input to the DA converter 10DAC. A target straight line for the improvement is not necessarily a straight line connecting the analog value of the bit string (1, 0, 0) and the analog value of the bit string (0, 0, 1), and may be a straight line interpolation using the analog values of the other two bit strings or a straight line acquired using regression analysis.

In Embodiment 1, in the calibration test by the processor 10P, a plurality of pairs (hereinafter, also referred to as test pairs) of a test bit string (sometimes abstracted and referred to as a test input value) and a test result bit string (sometimes abstracted and referred to as a test result value) having the following characteristics (A1) and (A2) are acquired:

(A1) The test bit string is the processor output bit string or the body input bit string for a calibration test. It is noted that, from another viewpoint, the test bit string may be regarded as a value input to the body circuit with or without correction as the DA conversion target value.

(A2) The test result bit string is acquired by converting the body output analog value by the AD converter. From another viewpoint, the test result bit string may be regarded as a value obtained by the AD converter performing AD conversion on an analog signal output by inputting the test input value to the body circuit.

Here, the conversion relation between the digital value (bit string) and the analog value of the DA converter 10DAC(A) described above is obtained by collecting the plurality of test pairs or processing the collection.

Although a plurality of embodiments will be described below, in each of the embodiments, in order to shorten a time for the test processing, an internal structure of the DA converter 10DAC(A) is considered, thereby reducing the number of pairs related to the above-described test. More specifically, as shown in FIG. 1, the DA converter 10DAC(A) reduces the number of test pairs in consideration of the structure of the DA converter (hereinafter, also referred to as a hybrid-type DA converter) that generates an analog value as a converter by adding an analog value output by a first type circuit segment SEG1 and an analog value output by a second type circuit segment SEG2.

In the case of a hybrid-type DA converter that supports multi-bit input with high accuracy while reducing a circuit scale in the DA converter, a circuit segment that is conscious of high accuracy (typically, in charge of MSB and bits (group) up to a predetermined number lower order than MSB) and a circuit segment that is conscious of low circuit scale mounting (typically, in charge of LSB and bits (group) up to a predetermined number upper order than LSB) are used together. Examples of such segments (first type circuit segment SEG1 and second type circuit segment SEG2) include a thermometer-type suitable for a high precision portion and a weighted binary-type (ladder-type) suitable for low circuit scale mounting. Taking a 3-bit hybrid-type DA converter (offset binary format or uncoded binary format) as an example, a high-accuracy conscious circuit segment (hereinafter, may be referred to as a high-accuracy circuit segment) is in charge of the MSB, and a low circuit scale conscious circuit segment (hereinafter, may be referred to as a low circuit scale mounting circuit segment) is in charge of the LSB and an intermediate bit. The above example is not intended to limit the technique of the present specification to a DA converter that handles an input in an offset binary format or an uncoded binary format. The technique of the present specification can also be applied to other binary formats (for example, two's complement binary format).

In the low circuit scale circuit segment, a common element is often used to output an analog value of a certain bit string and an analog value of another bit string. As an example of 3-bit, in both cases of a bit string (x, 0, 1) and a bit string (x, 1, 1), a common element in the low circuit scale circuit segment is used. Since the MSB is assumed to be in charge of a high-density mounting segment, it is omitted by x.

In each of the following embodiments, the “other test pair” is omitted by utilizing the fact that the test result bit string of the other test pair can be favorably estimated by acquiring one or more test pairs based on a relation between each of bits in the bit string and the used element in the circuit segment. As a result, the number of test pairs in one calibration test is smaller than the “number of bits of the test bit string” power of 2. From a different point of view, it can be said that the number of the test pairs acquired during the calibration test period is smaller than 2^{N} (N is the number of bits indicating the resolution of the correction target DA converter element), which is a result.

### <<Body Circuit Options>>

Main body circuit 10BDY according to Embodiment 1 may include the following options.

### <<<Amplifier Circuit AMP>>>

The amplifier circuit AMP amplifies the output of the DA converter 10DAC(A) when the output (output current or output voltage) of the DA converter 10DAC(A) is insufficient for operating the target device OBJ. An example of the amplifier circuit AMP is an operational amplifier, an amplifier circuit using an operational amplifier, or an amplifier circuit using a transistor (including an FET). The amplifier circuit AMP may use a circuit element (for example, a resistor) that may be affected by an operation environment (for example, a temperature). In order to correct such a fluctuation of the amplifier circuit, 10ANG(B) which is the output of the amplifier circuit AMP may be a conversion target of the AD converter 10AD instead of the body output analog value 10ANG(A). When the DA converter 10DAC(A) changes the current value as an analog value and outputs the current value, the amplifier circuit AMP may amplify the current value or may amplify the voltage value. When the DA converter 10DAC(A) changes the voltage value as an analog value and outputs the analog value, the amplifier circuit AMP may amplify the voltage value or may amplify the current value.

### <<<Attenuator>>>

The output of the DA converter 10DAC(A) or the output of the amplifier circuit AMP may be input to the AD converter 10AD via an attenuator (not shown). Since the attenuator can limit the voltage value or the current value input to the AD converter 10AD, it is possible to prevent the AD converter 10AD from being damaged by a high voltage value or a high current value. Even when the elements constituting the attenuator are affected by the operation environment, it is possible to correct the fluctuation of the attenuator.

### <<<DA Converter DAC(B)>>>

The body circuit 10BDY may include an additional DA converter 10DAC(B). The DA converter 10DAC(B) is used, for example, to convert the number of bits exceeding the number of bits that can be input to the DA converter 10DAC(A) into an analog value. Elements necessary for adding the DA converter 10DAC(B) include a division circuit 10SPT and a weighted addition circuit 10ADDW. Each role will be described later. The DA converter 10DAC(B) may not be a hybrid-type DA converter and may not be a correction target by a calibration test. Conversely, the DA converter 10DAC(B) may be a hybrid-type DA converter or may be a correction target by the calibration test.

### <<<Switch 10SW>>>

A switch 10SW switches whether the output of the DA converter 10DAC(A) is supplied to a target device OBJ side or an AD converter 10AD side. In FIG. 1, a state of the switch 10SW during a test to be described later is indicated by a solid line. In this state, the output of the DA converter 10DAC(A) is supplied to the AD converter 10AD. The switch 10SW is used when the body output analog value 10ANG during the test to be described later is not preferable for the target device OBJ.

The pre-stage 10FNT may circuit include optional components described in the body circuit 10BDY instead of the body circuit 10BDY. For example, the pre-stage circuit 10FNT may include a division circuit 10SPT(B) instead of a division circuit 10SPT(A) which is an option of the body circuit 10BDY. Such an example occurs when correction, which is a role of at least a part of the pre-stage circuit 10FNT, is improved by more closely cooperating with the DA conversion circuit.

The addition is not limited to the DA converter 10DAC(A), and a component element such as an operational amplifier is not necessarily required. For example, in the case of adding the current values, wirings from two current sources may be merged into one, and in the case of adding the voltage values, two voltage sources may be directly connected. In the following description, such a structure for addition may be referred to as an “addition circuit”. That is, the addition circuit may be only wiring. In addition, the “circuit” may be only a wiring not including an element.

The connection between the “wiring”, the processor 10P, the pre-stage circuit 10FNT, the body circuit 10BDY, and the AD converter 10AD may be a wiring formed on a substrate, a cable such as a coaxial cable, an optical cable, or a communication cable, an in-chip wiring pattern in an IC, or a wiring virtually defined in an FPGA. For example, a communication cable (for example, a network communication cable) may be adopted as a part or all of the connection between the processor 10P and the pre-stage circuit 10FNT. Therefore, the processor output bit string 10BTP may be transmitted in parallel through a plurality of wirings, or may be transmitted in a serialized manner as in a general communication method. The connection among the processor 10P, the pre-stage circuit 10FNT, the body circuit 10BDY, and the AD converter 10AD is not required to be directly connected only by wirings, and may include some components. Examples of the components include a photodiode for optical communication, a communication chip for communication using a network communication protocol (for example, USB, PCI, or Ethernet), timing adjustment, a hold circuit (element), and a band filter circuit (element) that are generally used in digital circuits and analog circuits. When the output, the input, and the transmission and reception of a bit string are described in the present specification, it is only necessary to output, input, and transmit and receive a bit string as a result, and it is not necessary to perform transmission while maintaining a “column” as in serial communication.

The components constituting the device 1 are not necessarily integrated into one housing, device, or substrate. In other words, each of the components may be implemented by a separate housing, device, or substrate.

### <Configuration Example of DA Converter 10DAC(A)>

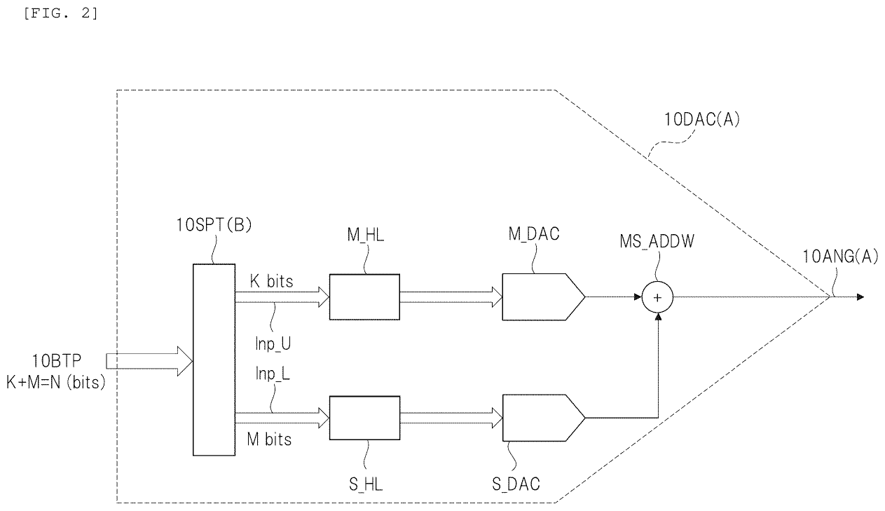

FIG. 2 is a block diagram showing a configuration of a DA converter according to Embodiment 1. As shown in FIG. 2, the

DA converter 10DAC(A) shown in FIG. 1 includes a main DA converter M_DAC, a sub DA converter S_DAC, a weighted addition circuit MS_ADDW, holding circuits M_HL and S_HL, and the division circuit 10SPT(B). Here, an example in which the division circuit 10SPT(B) is included in the DA converter 10DAC(A) in the body circuit 10BDY will be described, and the division circuit 10SPT(B) may be included in the pre-stage circuit 10FNT as shown in FIG. 1. In the following description, a DA converter that handles an input in an offset binary format or an uncoded binary format is taken as an example. However, the technique of the present specification can also be applied to a two's complement binary format (for example, a decoder circuit that performs binary format conversion may be included in the DA converter 10DAC(A).

FIG. 2 shows a case in which the number of bits of the processor output bit string (input bit string) 10BTP supplied from the processor 10P to the pre-stage circuit 10FNT and the body circuit 10BDY is N. The input bit string 10BTP of N bits is divided into an upper input bit string Inp_U and a lower input bit string Inp_L by the division circuit 10SPT(B). Here, describing the relation between the input bit string 10BTP and the upper input bit string Inp_U and the lower input bit string Inp_L, the number of bits K of the upper input bit string Inp_U+the number of bits M of the lower input bit string Inp_L=the number of bits N of the input bit string 10BTP. In addition, in the input bit string 10BTP, M−1 bits from a lowest bit LSB are extracted as the lower input bit string Inp_L by the division circuit 10SPT(B). Further, in the input bit string 10BTP, K bits from the M bits to an uppermost bit MSB are extracted as the upper input bit string Inp_U by the division circuit 10SPT(B).

The upper input bit string Inp_U is held in the holding circuit M_HL corresponding to the main DA converter M_DAC, and is supplied to the input of the main DA converter M_DAC. The lower input bit string Inp_L is held in the holding circuit S_HL corresponding to the sub DA converter S_DAC, and is supplied to the input of the sub DA converter S_DAC. The upper input bit string Inp_U is converted into a corresponding analog value by the main DA converter M_DAC, and the lower input bit string Inp_L is converted into a corresponding analog value by the sub DA converter S_DAC. The analog value obtained by the main DA converter M_DAC and the analog value obtained by the sub DA converter S_DAC are added by the addition circuit MS_ADDW and output as the analog value 10ANG(A) corresponding to the input bit string 10BTP.

Since the upper input bit string Inp_U is formed of bits on an uppermost bit MSB side, the analog value output from the main DA converter M-DAC greatly changes (roughly changes) when the bits constituting the upper input bit string Inp_U change. On the other hand, since the lower input bit string Inp_L is formed by bits on a lowest bit LSB side, the analog value output from the sub DA converter S_DAC slightly changes (finely changes) when the bits constituting the lower input bit string Inp_L change.

<<Configurations of DA Converters M_DAC and S_DAC and Addition Circuit MS_ADDW>>

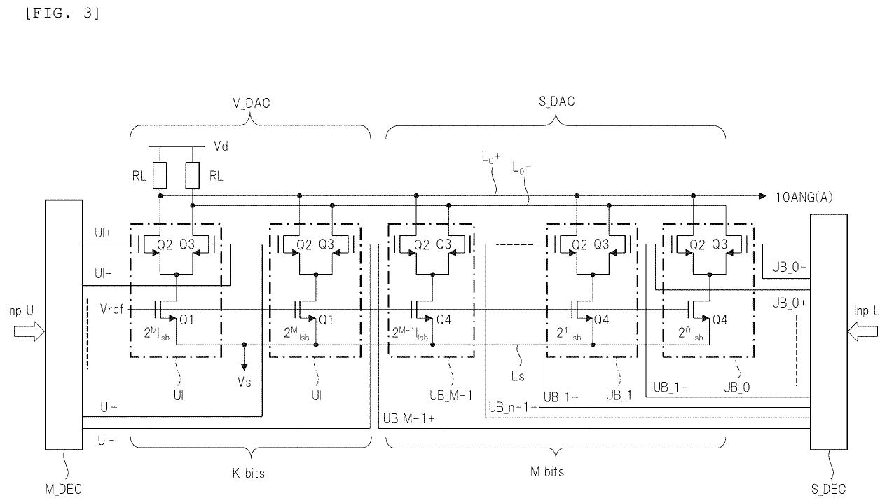

Next, a specific example of the main DA converter M_DAC, the sub DA converter S_DAC, and the addition circuit MS_ADDW shown in FIG. 2 will be described. FIG. 3 is a circuit diagram showing the configuration of the DA converter according to Embodiment 1.

In Embodiment 1, the main DA converter M_DAC is implemented by a thermometer-type DA converter (hereinafter, the same reference sign M_DAC), and the sub DA converter S_DAC is implemented by a weighted binary-type DA converter (hereinafter, the same reference sign S_DAC). The thermometer-type DA converter M_DAC corresponds to the first type circuit segment SEG1 shown in FIG. 1, and the weighted binary-type DA converter S_DAC corresponds to the second type circuit segment SEG2. Therefore, the DA converter 10DAC(A) is a segment-type DA converter in which the thermometer-type DA converter (first type circuit segment) M_DAC and the weighted binary-type DA converter (second type circuit segment) S_DAC are combined.

The input bit string from the division circuit 10SPT(B) is supplied to control circuits (hereinafter, also referred to as decoders) M_DEC and S_DEC. That is, the upper input bit string Inp_U from the division circuit 10SPT(B) is supplied to the decoder M_DEC. The decoder M_DEC outputs a plurality of complementary signals UI+ and UI− according to the code of the supplied upper input bit string Inp_U. That is, the signal UI+ is set to a high level by the number corresponding to the number represented by the code of the upper input bit string Inp_U, and the remaining signal UI+ is set to a low level. The signal UI− is in a complementary (inverted) relation to the paired signal UI+, and is at a low level when the paired signal UI+ is at a high level.

The lower input bit string Inp_L from the division circuit 10SPT(B) is supplied to the decoder S_DEC. The decoder S_DEC outputs complementary signals UB_0+, UB_0− to UB_M−1+, UB_M−1− corresponding to the code of the supplied lower input bit string Inp_L. The complementary signals UB_0+, UB_0− to UB_M−1+, and UB_M−1− correspond to bit 0 (lowest bit LSB) to bit M−1 constituting the lower input bit string Inp_L, and for example, when the bit 0 has a logical value “1”, the signal UB_0+ is at the high level (UB_0− is at the low level), and when the bit 0 has a logical value “0”, the signal UB_0+ is at the low level (UB_0− is at the high level). Similarly, the remaining complementary signals UB_1+, UB_1− to UB_M−1+, and UB_M−1− become the high level or the low level according to the logical value of the corresponding bit in the lower input bit string Inp_L.

### <<<Weighted Binary-Type DA Converter>>>

The weighted binary-type DA converter S_DAC includes a number of binary unit circuits (binary-type circuits, second type circuits) UB_0 to UB_M−1 corresponding to the number M of bit strings constituting the lower input bit string Inp_L. The binary unit circuit UB_0 corresponds to the lowest bit LSB of the lower input bit string Inp_L, and the binary unit circuits UB_1 to UB_M−1 correspond to the bit 1 to the bit M−1 in the lower input bit string Inp_L.

Each of the binary unit circuits UB_0 to UB_M−1 has a similar configuration. Taking the binary unit circuit UB_0 corresponding to the lowest bit LSB as an example, the binary unit circuit UB_0 includes transistors Q2 and Q3 whose drains are connected to the output lines Lo+ and Lo−, and a transistor Q4 connected between a common source of the transistors Q2 and Q3 and the ground line Ls. The transistors Q2 and Q3 are turned on and off by corresponding signals UB_0+ and UB_0− from the decoder S_DEC. A reference voltage Vref is supplied to a gate of the transistor Q4. The transistor Q4 functions as a constant current source that forms a predetermined constant current 2⁰I_{lsb} when the reference voltage Vref is supplied. For example, a size or the like of the transistor Q4 included in the binary unit circuit UB_0 is set to form a constant current corresponding to the lowest bit LSB. Therefore, for example, when the signal UB_0+ is at the high level, the transistor Q2 is turned on, and the predetermined constant current 2⁰I_{lsb} flows from the output line Lot to a ground line Ls via the transistor Q2.

The binary unit circuits UB_1 to UB_M−1 are different from the binary unit circuit UB_0 in that the size of the transistor Q4 is set such that a value of the constant current to be formed becomes a value corresponding to the bit 1 to the bit M−1 of the lower input bit string Inp_L. For example, the transistor Q4 of the binary unit circuit UB_M−1 is set such that a constant current 2^{M-1}I_{lsb} corresponding to the bit M−1 of the lower input bit string Inp_L flows.

Accordingly, in the weighted binary-type DA converter S_DAC, the constant current corresponding to the bit flows from the output line Lot to the ground line Ls via the binary unit circuit corresponding to the bit having the logical value “1” in the lower input bit string Inp_L. As a result, the lower input bit string Inp_L is converted into a corresponding current value.

### <<<Thermometer-Type DA Converter>>>

The thermometer-type DA converter M_DAC includes the number of thermo unit circuits (thermometer circuits, first type circuits) UI according to the number of bits K of the upper input bit string Inp_U. That is, the thermometer-type DA converter M_DAC includes the thermo unit circuits UI whose number is power of 2 (2\hat{ }K) with the number of bits K as an exponent. The thermo unit circuits UI are connected in parallel between the output lines Lo+ and Lo− and the ground line Ls.

These thermo unit circuits UI have the same configuration. As shown in FIG. 3, each of the thermo unit circuits UI includes a transistor Q1 to which the reference voltage Vref is supplied, and the transistors Q2 and Q3 that operate complementarily to each other.

The transistor Q1 functions as a constant current source that forms a predetermined constant current when the reference voltage Vref is supplied to the gate. The value of the formed constant current is a current 2^{M}I_{lsb} corresponding to the lowest bit M in the upper input bit string Inp_U.

In the thermometer-type DA converter M_DAC, since the transistors Q2 in the number of thermo unit circuits UI represented by the code of the upper input bit string Inp_U are turned on, a current according to the number represented by the upper input bit string Inp_U flows from the output line Lot to the ground line Ls. As a result, the upper input bit string Inp_U is also converted into a corresponding current value.

As shown in FIG. 3, the output lines Lo+ and Lo− are connected to a voltage Vd via a load resistor RL. That is, the load resistor RL is common to the thermometer-type DA converter M_DAC and the binary-type DA converter S_DAC. Accordingly, the output of the thermometer-type DA converter M_DAC and the output of the binary-type DA converter S_DAC are added. That is, the addition circuit MS_ADDW shown in FIGS. 1 and 2 is implemented by the common output lines Lo+ and Lo− and the load resistor RL.

### <<<Correspondence to Input in Various Binary Formats>>>

The hybrid-type DA converter 10DAC(A) assuming the offset binary format or the uncoded binary format is described above. When the input of the two's complement binary format is handled, a decoder circuit for converting the two's complement binary format input in the converter into the offset binary format may be disposed between the division circuit 10SPT(B) and an input terminal. Other implementation examples are also conceivable. For example, the division circuit 10SPT(B) may receive a bit string in the two's complement binary format, and divide the bit string into the upper input bit string Inp_U and the lower input bit string Inp_L, also in the two's complement binary format, and output the bit strings. In this case, the decoder of each segment handles the two's complement binary format. In view of the above implementation example, the division circuit may be regarded as a circuit that outputs an internal upper bit string of K bits and an internal lower bit string of M bits based on the input value from the input terminal and the binary format assumed to be input by the element.

### <Calibration Test of DA Converter>

As described above, linearity (INL) is known as accuracy of the DA converter. The linearity of the DA converter 10DAC(A) shown in FIG. 1 fluctuates depending on, for example, a change in an environmental temperature. In Embodiment 1, in order to improve the accuracy of the DA converter 10DAC(A), the calibration test is executed by the DA converter 10DAC(A) before actually performing a conversion operation, and the input bit string of the DA converter 10DAC(A) is corrected by the pre-stage circuit 10FNT shown in FIG. 1 based on a correction amount obtained by the calibration test.

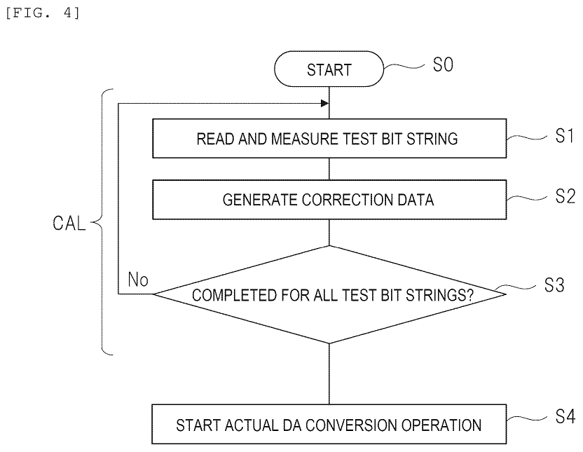

FIG. 4 is a flowchart when the DA converter 10DAC(A) according to Embodiment 1 is operated. In step S0, the DA converter 10DAC(A) starts operating. Thereafter, in a calibration period CAL, the processor 10P (FIG. 1) executes steps S0 to S3 to perform the calibration test of the DA converter 10DAC(A). That is, in step S1, the processor 10P reads a test bit string from test data, inputs the read test bit string as an input bit string to the DA converter 10DAC(A), and measures an output of the DA converter. In step S2, the processor 10P generates a correction amount using the output of the DA converter 10DAC(A) measured in step S1 and the test bit string. Thereafter, the processor 10P determines whether the measurement and the generation of the correction amount by all the test bit strings are completed in step S3. When it is determined in step S3 that the processing is not completed for all the test bit strings, the processor 10P returns to step S1. That is, in the calibration period CAL, the processor 10P repeatedly executes steps S1 to S3.

After the calibration test is completed, the DA converter 10DAC(A) performs an actual DA conversion operation in step S4.

In order to reduce the fluctuation in the accuracy of the DA conversion circuit due to an environmental temperature change and improve the accuracy, it is conceivable to increase a frequency of performing the calibration test. However, when the calibration period CAL is long, the frequency of actually performing the DA conversion operation decreases. When the calibration period CAL is long, it is conceivable to divide the calibration period CAL into a plurality of periods and perform the calibration test in a distributed manner, but in this case, a time when the correction is finally completed is delayed, and the accuracy decreases until the correction is completed.

The test bit string has the same number of bits as the input bit string 10BTP actually input to the DA converter 10DAC(A), and generally, the test bit strings corresponding to all combinations of codes of the input bit string 10BTP are prepared as the test data. That is, as described above, in the case of the input bit string 10BTP having the number of bits N (the number of bits of the upper input bit string: K bits+the number of bits of the lower input bit string: M bits), power of 2 (2\hat{ }N) test bit strings having the number of bits N as an exponent are prepared as the test data. In order to increase the resolution of the DA converter 10DAC(A), it is necessary to increase the number of bits of the input bit string, which causes a problem that the calibration period CAL becomes long.

### <Test Data>

In Embodiment 1, in order to shorten the calibration period CAL, a test bit string considering the structure of the DA converter 10DAC(A) is used. Here, as described with reference to FIGS. 2 and 3, a case in which the DA converter 10DAC(A) is implemented by the thermometer-type DA converter M_DAC and the weighted binary-type DA converter S_DAC will be described as an example.

### <<Test Bit String of Weighted Binary-Type DA Converter>>

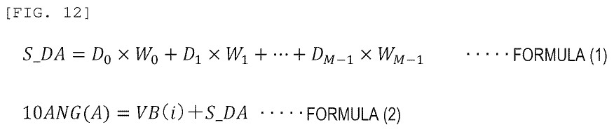

The relation between the lower input bit string Inp_L input to the weighted binary-type DA converter S_DAC shown in FIG. 3 and the output of the DA converter is represented by Formula (1) shown in FIG. 12. In Formula (1), D₀ to D_{M-1} represents a bit constituting the lower input bit string Inp_L. That is, the bit D₀ corresponds to the lowest bit LSB of the lower input bit string Inp_L, and the bit D_{M-1} corresponds to the uppermost bit of the lower input bit string Inp_L. The decoder S_DEC shown in FIG. 3 outputs the signals UB_0+ and UB_0− according to a logical value of the bit D₀. For example, when the logical value of the bit D₀ is “1”, the decoder S_DEC outputs a high level signal UB_0+. D₁ to D_{M-1} are the same as the bit D₀, and the decoder S_DEC sets the corresponding signals UB_1+ to UB_M−1+ to the high level when the logical value of the bit is “1”.

In addition, in Formula (1), W₀ to W_{M-1} indicates a value of the constant current formed by the constant current source (transistor Q4) in the binary unit circuits UB_0 to UB_M−1. For example, the current value W₀ indicates the value of the constant current formed by the transistor Q4 of the binary unit circuit UB_0.

As can be understood from Formula (1), a current value S_DA output by the weighted binary-type DA converter S_DAC is a value of a constant current when the desired bit has a logical value “1” by setting the desired bit to the logical value “1” and setting all the other bits to the logical value “0” in the lower input bit string Inp_L. This indicates that, for example, when the logical value of the bit D₀ is set to “1” and all the logical values of the bit D₁ to D_{M-1} are set to “0”, the value of the constant current corresponding to the bit D₀ can be measured as the current value S_DA output from the weighted binary-type DA converter S_DAC.

When a plurality of bits have the logical value “1” in the lower input bit string Inp_L, the value of the constant current output from the DA converter S_DAC when the plurality of bits have the logical value “1” in the lower input bit string Inp_L can be calculated by combining (adding) the current value S_DA measured in advance with the bit having the logical value “1”. For example, in the lower input bit string Inp_L, when both the bit D₀ and the bit D₁ have the logical value “1” and all the remaining bits have the logical value “0”, the current value S_DA output from the weighted binary-type DA converter S_DAC can be calculated by adding the current value S_DA measured in advance for the bit D₀ and the current value S_DA measured in advance for the bit D₁.

That is, if the output of the weighted binary-type DA converter S_DAC when only one bit has the logical value “1” in the lower input bit string Inp_L is measured, the output of the weighted binary-type DA converter S_DAC when a plurality of bits have the logical value “1” at the same time in the lower input bit string Inp_L can also be calculated using the measured value.

In consideration of the structure of the weighted binary-type DA converter, in the weighted binary-type DA converter S_DAC according to Embodiment 1, as the test bit string corresponding to the lower input bit string Inp_L, M bit strings in which any one of the bits D₀ to D_{M-1} has the logical value “1” and all the other bits have the logical value “0” are used.

The weighted binary-type DA converter S_DAC may have a direct current offset DC_Offset. Therefore, in Embodiment 1, a test bit string in which all logical values of D₀ to D_{M-1} are set to “0” is also used. Therefore, the number of test bit strings for the weighted binary-type DA converter S_DAC according to Embodiment 1 is M+1.

### <<Test Bit String of Thermometer-Type DA Converter>>

In the thermometer-type DA converter M_DAC, the constant currents of the number of thermo unit circuits UI corresponding to the number represented by the code of the input bit string are added to obtain the current value output from the thermometer-type DA converter M_DAC.

In Embodiment 1, the same bit string as all codes that can be input to the thermometer-type DA converter M_DAC is set as the test bit string. That is, the number of test bit strings for the thermometer-type DA converter M_DAC is power of 2 (2\hat{ }K) with the number of bits K of the upper input bit string Inp_U as an exponent.

As a result, in the calibration period CAL, the number of test bit strings supplied to the DA converter 10DAC(A) (FIG. 2) according to Embodiment 1 is the sum (M+1+2\hat{ }K) of the number M+1 of test bit strings for the weighted binary-type DA converter S_DAC and the number 2\hat{ }^{K} of test bit strings for the thermometer-type DA converter M_DAC, and can be reduced as compared with the number (2\hat{ }^{N}) of the test bit strings corresponding to all codes represented by the input bit string. For example, when the number of bits K of the upper input bit string Inp_U is 7, the number of bits M of the lower input bit string Inp_L is 7, and the number of bits N(=K+M) of the input bit string 10BTP is 14 (in the case of resolution N bits), the number of test bit strings corresponding to all codes is 2\hat{ }¹⁴=16384. On the other hand, according to Embodiment 1, the number of test bit strings is 7+1+2\hat{ }⁷=136. That is, in the calibration period CAL, the number of times of supplying the test bit string to the DA converter 10DCA(A) and measuring the output thereof can be significantly reduced to 136.

The test data for the thermometer-type DA converter M_DAC and the test data for the weighted binary-type DA converter S_DAC determined as described above are stored in the nonvolatile memory NVMEM or the volatile memory VOLMEM shown in FIG. 1 before the calibration test is executed.

### <Operation of Calibration Test>

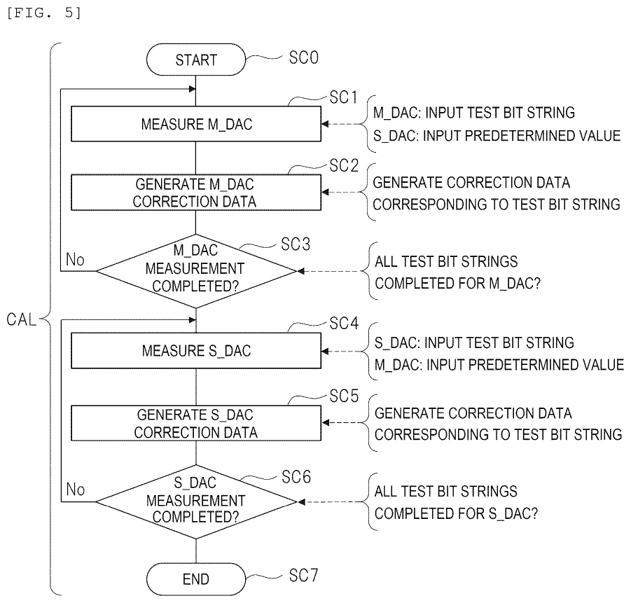

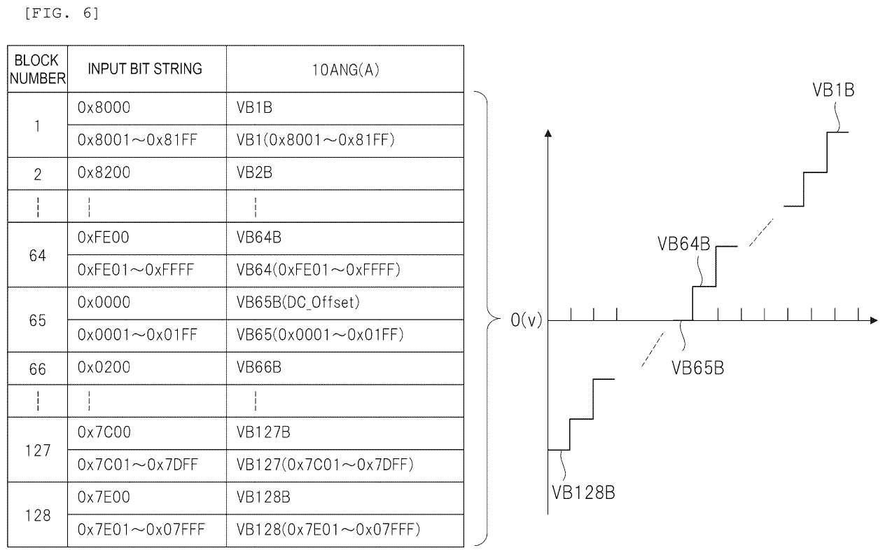

FIG. 5 is a flowchart showing the calibration test according to Embodiment 1. FIG. 6 is a diagram showing the calibration test according to Embodiment 1. Hereinafter, the operation of the calibration test will be described with reference to FIGS. 1, 2, 5, and 6.

In FIG. 5, in step SC0, the processor 10P starts calibration test. Here, an example will be described in which the calibration test of the thermometer-type DA converter M_DAC (hereinafter, also simply referred to as the DA converter M_DAC) is performed before the weighted binary-type DA converter S_DAC (hereinafter, also simply referred to as the DA converter S_DAC), and the invention is not limited thereto. That is, the DA converter S_DAC may be first subjected to the calibration test.

In step SC1, the processor 10P reads the test bit string from the test data stored in the nonvolatile memory NVMEM or the volatile memory VOLMEM, and inputs the test bit string as the upper input bit string Inp_U to the DA converter M_DAC constituting the DA converter 10DAC(A) via the pre-stage circuit 10FNT. At this time, the processor 10P inputs a bit string in which all logical values are “0” (lower input bit string of a predetermined value) as the lower input bit string Inp_L to the DA converter S_DAC constituting the DA converter 10DAC(A). The processor 10P controls the switch 10SW (FIG. 1) such that the output of the DA converter 10DAC(A) is supplied to the AD converter 10AD.

Accordingly, the analog value corresponding to the test bit string converted by the DA converter M_DAC is supplied to the AD converter 10AD, converted into a digital string corresponding to the supplied analog value by the AD converter 10AD, and supplied to the processor 10P as the test result bit string 10BTTR (FIG. 1).

In step SC2, the processor 10P compares the test bit string supplied to the DA converter M_DAC in step SC1 with the supplied test result bit string, and generates input and output characteristics of the DA converter M_DAC based on the test bit string. Based on the generated input and output characteristics, the processor 10P generates a correction amount such that the test result bit string matches the test bit string, and stores the correction amount in the memory of the pre-stage circuit 10FNT as the correction data (correction D in FIG. 1). At this time, the processor 10P stores the generated correction amount so as to be paired with the supplied test bit string.

Next, in step SC3, the processor 10P determines whether the test of the DA converter M_DAC using all the test bit strings is completed. This is achieved, for example, by the processor 10P determining whether all pieces of the test data to be supplied to the DA converter M_DAC are read from the nonvolatile memory NVMEM or the volatile memory VOLMEM. When the processor 10P determines that the test using all the test bit strings is not completed, the processor 10P returns to step SC1, reads the test bit string that is not read, and repeatedly executes steps SC1 to SC3.

An output voltage range represented by the input bit string Input input to the DA converter 10DAC(A) is divided into a plurality of blocks 1 to 128 by the code of the upper input bit string Inp_U input to the DA converter M_DAC, as shown in the table on the left side of FIG. 6. The code of the upper input bit string Inp_U indicates a unique base voltage value of each block, and the code of the lower input bit string Inp_L indicates a common voltage value for each block. For example, when the upper input bit string Inp_U has a logical value “0x8000”, the block 1 is identified, and the upper input bit string Inp_U indicates a base voltage VB1B of the block 1, and when the upper input bit string Inp_U has a logical value “0x0000”, the block 65 is identified, and the upper input bit string Inp_U indicates a base voltage VB65B of the block 65.

The analog value 10ANG(A) output from the DA converter 10DAC(A) by converting the input bit string is represented by Formula (2) shown in FIG. 12. In Formula (2), VB (i) indicates a base voltage indicated by the upper input bit string Inp_U. As can be understood from Formula (2), the analog value 10ANG(A) corresponding to the input bit string 10BTP is obtained by adding the common voltage value indicated by the code of the lower input bit string Inp_L to the base voltage value identified by the code of the upper input bit string Inp_U. Therefore, in step SC1, by inputting a predetermined value (all logical values are “0”) to the DA converter S_DAC as the lower input bit string Inp_L, the upper input bit string Inp_U indicates the base voltage VB (i) of the block indicated by the upper input bit string.

In FIG. 6, the graph on the right side shows a relation between the block number and the base voltage. In the graph, a horizontal axis represents the block number, and a vertical axis represents the base voltage. Although not particularly limited, as understood from the graph, the DA converter 10DAC(A) according to Embodiment 1 converts the input bit string 10BTP to a positive voltage side and a negative voltage side with reference to a ground voltage (0 V). As the direct current offset DC_Offset, the value of the base voltage at the time of the block number 65 corresponding to the ground voltage (0 (V)) at which an output noise is small is used. That is, an output value of the DA converter 10DAC(A) when the test bit string corresponding to the logical value “0x000” is supplied to the DA converter 10DAC(A) is the direct current offset DC_Offset. In other words, the lower input bit string Inp_L is set to a predetermined value (all logical values are “0”), the upper input bit string Inp_U is also set to a predetermined value (all logical values are “0”), and the direct current offset DC_Offset is acquired.

Next, the calibration test of the DA converter S_DAC will be described.

The processor 10P executes step SC4 after step SC3. In step SC4, the processor 10P reads the test bit string related to the DA converter S_DAC stored in the nonvolatile memory NVMEM or the volatile memory VOLMEM, and inputs the test bit string to the DA converter S_DAC as the lower input bit string Inp_L. At this time, the processor 10P inputs a bit string in which all logical values are “0” (upper input bit string of a predetermined value) as the upper input bit string Inp_U to the DA converter M_DAC. In addition, the processor 10P controls the switch 10SW such that the output of the DA converter 10DAC(A) is supplied to the AD converter 10AD.

Accordingly, the analog value corresponding to the test bit string converted by the DA converter S_DAC is supplied to the AD converter 10AD, converted into the corresponding digital string by the AD converter 10AD, and supplied to the processor 10P as the test result bit string 10BTTR.

In step SC5, the processor 10P compares the test bit string supplied to the DA converter S_DAC in step SC3 with the supplied test result bit string, and generates the input and output characteristics of the DA converter S_DAC based on the test bit string. Based on the generated input and output characteristics, the processor 10P generates a correction amount such that the test result bit string matches the test bit string, and stores the correction amount in the memory of the pre-stage circuit 10FNT as the correction data (correction D in FIG. 1). At this time, the processor 10P stores the generated correction amount so as to be paired with the supplied test bit string.

Next, in step SC6, the processor 10P determines whether the test of the DA converter S_DAC using all the test bit strings is completed. This can be determined by, for example, the same method as in step SC3 described above. In step SC6, when the processor 10P determines that all the test bit strings are not read, the processor 10P returns to step SC4, reads the test bit string that is not read, and repeatedly executes steps SC4 to SC6.

When step SC6 ends, the processor 10P ends the operation of the calibration test in step SC7.

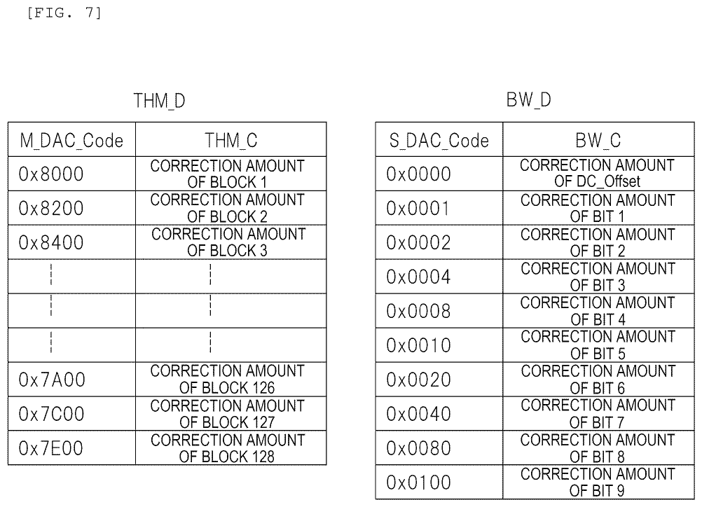

FIG. 7 is a diagram showing the correction amount according to Embodiment 1. FIG. 7 shows an example of the correction amount generated by the processor 10P by executing the calibration test described in FIG. 6 and stored as the correction data (correction D) in the pre-stage circuit 10FNT.

In FIG. 7, THM_D indicates an area corresponding to the DA converter M_DAC and storing a plurality of correction amounts generated by executing steps SC1 to SC3, and BW_D indicates an area corresponding to the DA converter S_DAC and storing a plurality of correction amounts generated by executing steps SC4 to SC6. As shown in FIG. 7, the correction amount of the direct current offset DC_Offset is stored in the area BW_D.

In the area THM_D, a column of M_DAC_Code indicates an area in which a test bit string corresponding to the upper input bit string Inp_U is stored, and a column of THM_C indicates an area in which a correction amount is stored. In FIG. 7, the correction amount of the block number corresponding to the test bit string is stored in the area THM_C. In the area TMH_D, a test bit string and a correction amount are stored in pairs so as to correspond to each other. For example, the correction amount of the block number 1 is stored so as to be paired with the test bit string “0x8000” indicating the block number 1.

In addition, in the area BW_D, the column of S_DAC_Code indicates an area in which the test bit string corresponding to the lower input bit string Inp_L is stored, and BW_C indicates an area in which the correction amount of the bit number corresponding to the test bit string is stored. For example, the correction amount of the bit 1 is stored so as to be paired with the test bit string “0x0001” in which only the bit 1 has the logical value “1”. As the correction data corresponding to the test bit string “0x0000”, the direct current offset DC_Offset is stored as a pair.

### <Correction>

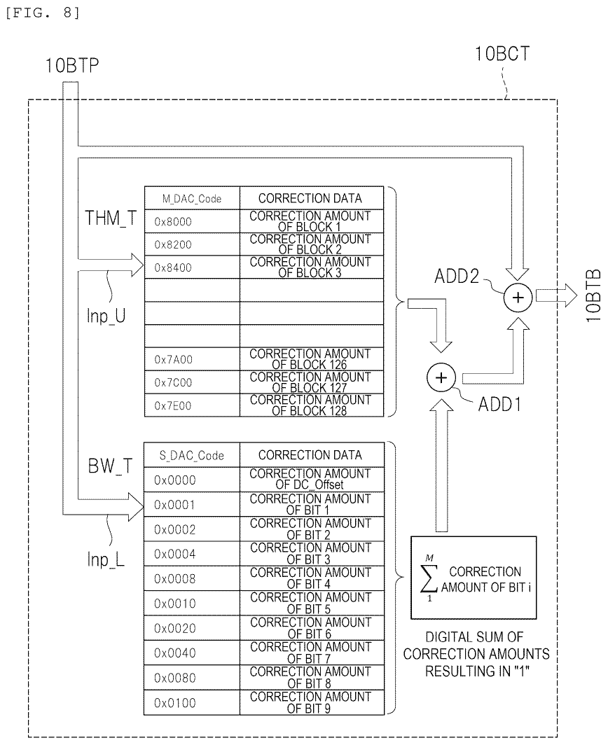

Next, the correction performed in the pre-stage circuit 10FNT will be described with reference to the drawings. FIG. 8 is a block diagram showing a configuration of the bit string correction circuit according to Embodiment 1.

The bit string correction circuit 10BCT includes a table THM_T corresponding to the upper input bit string Inp_U, a table BW_T corresponding to the lower input bit string Inp_L, and adders ADD1 and ADD2.

The processor 10P transmits the correction amount of the test bit string and the block number stored in the area THM_D (FIG. 7) to the table THM_T, and transmits the correction amount of the test bit string and the bit stored in the area BW_D (FIG. 7) to the table BW_T. Accordingly, as shown in FIG. 8, the test bit string corresponding to the upper input bit string Inp_U and the correction amount corresponding thereto are registered as a pair in the table THM_T, and the test bit string corresponding to the lower input bit string Inp_L and the correction amount corresponding thereto are registered as a pair in the table BW_T.

The table THM_T is searched by the upper input bit string Inp_U of the input bit string 10BTP, and the table THM_T outputs the correction amount corresponding to the test bit string matching the upper input bit string Inp_U. The output correction amount is supplied to the adder ADD1.

The table BW_T is searched by the lower input bit string Inp_L of the input bit string 10BTP. In the search, in the lower input bit string Inp_L, a test bit string in which the same bit number as the bit number whose logical value is “1” is the logical value “1” is searched. By the search, the correction amount corresponding to the test bit string in which the logical value of the same bit number is “1” is output from the table BW_T. In the lower input bit string Inp_L of the input bit string 10BTP, a plurality of different bit numbers may have a logical value “1” at the same time. In this case, a plurality of correction amounts are output from the table BW_T. To cope with this, a sum of the correction amounts output from the table BW_T is digitally obtained. The obtained correction amount of the sum is supplied to the adder ADD1.

The adder ADD1 adds the correction amounts from the table THM_T and the correction amounts (sum of the correction amounts) from the table BW_T, and supplies the correction amounts to the adder ADD2. The adder ADD2 adds the input bit string 10BTP and the correction amount from the adder ADD1 and supplies the result to the input of the DA converter 10DAC(A).

Accordingly, the body input bit string 10BTB supplied to the DA converter 10DAC(A) is corrected by the pre-stage circuit 10FNT based on the correction amount obtained in the calibration test. That is, the input bit string input to the DA converter 10DAC(A) is corrected based on the input and output characteristics of the DA converter 10DAC(A), and the accuracy is improved.

Since the number of test bit strings to be used in the calibration test can be reduced, the calibration period CAL can be shortened. Therefore, it is possible to shorten an execution interval of the calibration test so as to cope with the fluctuation of the environmental temperature.

In addition, since the number of correction amounts for corresponding to the lower input bit string Inp_L is the number of bits M+1 constituting the lower input bit string Inp_L, it is possible to prevent the table BW_T and the area BW_D of the memory 100 from becoming large.

In Embodiment 1, the bit string correction circuit 10BCT of the pre-stage circuit 10FNT includes the adders as shown in FIG. 8, for example, and the adder may be omitted. This can be achieved by, for example, registering not only the correction amount but also a value obtained by adding a value indicated by the original processor output bit string 10BTP to the correction amount in the tables THM_T and BW_T, and outputting a value obtained by correcting the processor output bit string from the bit string correction circuit 10BCT.

The DA converter 10DAC(A) may include a plurality of DA converters, a plurality of division circuits, and a plurality of weighting addition circuits.

Although FIGS. 4 and 5 show an example in which the steps of measuring the test result bit string corresponding to the test bit string and generating the correction amount is repeated, the method for generating the correction amount is not limited thereto. For example, the correction amount may be generated by creating a target DA conversion relation by regression analysis (linear regression). That is, all measurements may be performed, and then the correction amount may be generated.

In Embodiment 1, the example in which the correction data is created by the calibration test is described, and the invention is not limited thereto. That is, for example, the already created correction data may be updated by the calibration test. In this case, the pre-stage circuit performs the correction based on the updated correction data. In the following description, both creation and update of the correction data may be referred to as update of the correction data.

In Embodiment 1, the update of the correction data or the generation of the test input value is performed based on the relation between the bit group included in the bit string input to the DA converter 10DAC(A) and the first type circuit segment SEG1 and the second type circuit segment SEG2.

In Embodiment 1, an example in which an uncorrected value is used as a test input value that is a test pair is described, and the invention is not limited thereto. That is, for example, the calibration test may be performed using a corrected value as the test input value.

As shown in FIG. 2, the division circuit 10SPT(B) outputs the internal upper bit (Inp_U) of K bits to the first type circuit segment (M_DAC), and outputs the internal lower bit (Inp_L) of M bits to the second type circuit segment (S_DAC). The calibration test includes a first type-oriented test for grasping the DA conversion characteristics of the first type circuit segment (M_DAC) and a second type-oriented test for the DA conversion characteristics of the second type circuit segment (S_DAC). In this case, as shown in FIG. 5, a first type-oriented test input value to be used in the first type-oriented test is a value adjusted so that the internal lower bit string becomes the second fixed bit string (predetermined value input in step SC1). As shown in FIG. 5, the second type-oriented test input value to be used in the second type-oriented test is a value adjusted so that the internal upper bit string becomes the first fixed bit string (predetermined value input in step SC4). Accordingly, it is possible to reduce the influence of the second type circuit segment during the first type-oriented test, and to reduce the influence of the first type circuit segment during the second type-oriented test.

In the calibration test, as shown in FIG. 6, an offset measurement test is performed to obtain an analog value independent of the values of the internal upper bit string and the internal lower bit string. In this case, as shown in FIG. 6, the first fixed bit string and the second fixed bit string “0x0000” are input to the first type circuit segment (M_DAC) and the second type circuit segment (S_DAC).

The calibration test according to Embodiment 1 can be regarded as not including the first reduction target test using a first reduction target test input value. Here, the first reduction target test input value has an internal upper bit string that is a value other than the first fixed bit string (M_DAC in FIG. 5: predetermined value input) and an internal lower bit string that is a value other than the second fixed bit string (S_DAC in FIG. 5: predetermined value input).

The calibration test according to Embodiment 1 can be regarded as including the first reduction target test using the first reduction target test input value. Here, the first reduction target test input value has an internal upper bit string that is a value other than the first fixed bit string, and the internal lower bit string that is a value other than the second fixed bit string, and the number of test pairs to be used in the first reduction target test is 2N−(2^{K}+2^{M}+1).

In FIG. 3, the decoder M_DEC can be regarded as a selector that selects one first type circuit from the plurality of first type circuits UI. In this case, the selector supplies an active signal (high level signal UI+) to a selected first type circuit, and supplies an inactive signal (high level signal UI−) to a non-selected first type circuit. Considering active/inactive states of the first type circuit and the second type circuit shown in FIG. 3, the update of the correction data or the generation of the test input value is performed based on the relation between the bit group included in the bit string input to the DA converter 10DAC(A) and the active/inactive states of the first type circuit and the second type circuit.

The number of test pairs acquired in the calibration test is equal to or larger than the total number of the first type circuits and the second type circuits described in FIG. 3.

In FIG. 8, the table THM_T can be regarded as a first table for managing the correction amount derived from the first type circuit segment, and the table BW_T can be regarded as a table for managing the correction amount derived from the second type circuit segment.

Although an example in which the processor output bit string 10BTP is used as the test bit string is described, the body input bit string 10BTB may be used as the test bit string.

### Embodiment 2

In Embodiment 1, a device using one DA converter 10DAC(A) is described. In Embodiment 2, a device using a plurality of DA converters will be described. That is, a case in which the body circuit 10BDY includes an additional DA converter 10DAC(B) in addition to the DA converter 10DAC(A) will be described as Embodiment 2. By adding the DA converter 10DAC(B), the number of bits that can be input to the DA converter can be increased. In this case, as described above, the body circuit 10BDY further includes the division circuit 10SPT(A) and the weighted addition circuits 10ADDW.

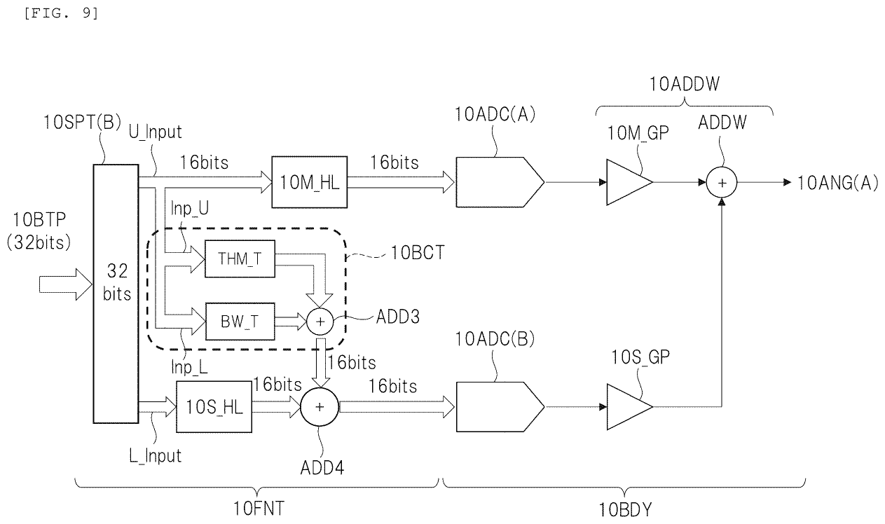

FIG. 9 is a block diagram showing a configuration of the device according to Embodiment 2. FIG. 9 shows the body circuit 10BDY and the pre-stage circuit 10FNT according to Embodiment 2.

### <Body Circuit>

In FIG. 9, the body circuit 10BDY includes the DA converter 10DAC(A), the DA converter 10DAC(B), and the weighted addition circuits 10ADDW. As shown in FIG. 2, the DA converter DAC(A) includes the division circuit, the holding circuits M_HL and S_HL, the main DA converter M_DAC, the sub DA converter S_DAC, and the addition circuit MS_ADDW. In the DA converter DAC(A) according to Embodiment 2, the division circuit 10SPT(B) provided in the body circuit 10BDY is used as the division circuit.

The output of the DA converter 10DAC(A) and the output of the DA converter 10DAC(B) are added by the addition circuit 10ADDW and supplied as the analog value to the amplifier circuit AMP or the AD converter 10AD via the switch 10SW (FIG. 1). In Embodiment 2, although not particularly limited, the addition circuit 10ADDW includes a gain amplifier 10M_GP to which an output from the DA converter 10DAC(A) is supplied, a gain amplifier 10S_GP to which an output from the DA converter 10DAC(B) is supplied, and an adder ADDW that adds the output of the gain amplifier 10M_GP and the output of the gain amplifier 10S_GP and outputs the result.

### <Pre-Stage Circuit>

As shown in FIG. 9, the pre-stage circuit 10FNT includes the bit string correction circuit 10BCT, the division circuit 10SPT(B), a holding circuits 10M_HL and 10S_HL, and an adder ADD4. In Embodiment 1, the bit string correction circuit 10BCT mainly adds and outputs the processor output bit string 10BTP using the adder ADD2 of FIG. 8. On the other hand, in Embodiment 2, such addition as the bit string correction circuit 10BCT is not performed as shown in FIG. 9. This is because the adder ADD4 performs a similar role.

The processor output bit string 10BTP from the processor 10P is supplied to the division circuit 10SPT(B). Here, although not particularly limited, a case in which the processor output bit string 10BTP is 32 bits will be described as an example. That is, it is assumed that 32 bits parallel in time are set as one bit string, and the bit string is supplied from the processor 10P to the pre-stage circuit 10FNT.

The division circuit 10SPT(B) divides the supplied 32-bit processor output bit string 10BTP into an upper bit string U_Input and a lower bit string L_Input. Here, it is assumed that the upper bit string U_Input includes 16 bits on the uppermost bit MSB side of the processor output bit string 10BTP, and the lower bit string L_Input includes 16 bits on the lowest bit LSB side of the processor output bit string 10BTP. Of course, 32 bits and 16 bits are examples, and the invention is not limited thereto.

The upper bit string U_Input is held by the holding circuit 10M_HL and input to the DA converter 10DAC(A). On the other hand, the lower bit string L_Input is held by the holding circuit 10S_HL and supplied to the adder ADD4. The output of the adder ADD4 is input to the DA converter 10DAC(B). The output of the DA converter 10DAC(A) and the output of the 10DAC(B) are added by the weighted addition circuit 10ADDW and output as, for example, the analog value 10ANG(A).

The bit string correction circuit 10BCT includes tables THM_T and BW_T and an adder ADD3. The table (first table) THM_T and the table (second table) BW_T are searched by the upper bit string U_Input, and the correction amount found by the search is added by the adder ADD3. An addition result of the adder ADD3 is supplied to the adder ADD4. Therefore, the adder ADD4 adds the correction amount from the bit string correction circuit 10BCT to the lower bit string L_Input. That is, the lower bit string L_Input is corrected by the correction amount from the bit string correction circuit 10BCT.

The DA converter 10DAC(A) according to Embodiment 2 is implemented by the segment-type DA converter described with reference to FIGS. 2 and 3. That is, the DA converter 10DAC(A) includes the thermometer-type DA converter M_DAC and the weighted binary-type DA converter S_DAC.

In Embodiment 2, the correction of the DA converter 10DAC(A) whose voltage greatly changes depending on the value of the input bit string is performed. Therefore, in the calibration period CAL, a test bit string suitable for the configurations of the thermometer-type DA converter M_DAC and the weighted binary-type DA converter S_DAC constituting the DA converter 10DAC(A) is supplied from the processor 10P (FIG. 1) to the DA converter 10DAC(A) as the upper bit string U_Input.

That is, in the same manner as described in Embodiment 1, test data constituted by a test bit string derived from the structure of the thermometer-type DA converter M_DAC constituting the DA converter 10DAC(A) and test data constituted by a test bit string derived from the structure of the weighted binary-type DA converter S_DAC constituting the DA converter 10DAC(A) are prepared in advance.

As described in Embodiment 1, the processor 10P supplies the test bit string to the DA converter 10DAC(A) via the pre-stage circuit 10FNT using the prepared test data, and generates the correction amount based on the test result bit string and the test bit string from the AD converter 10AD (FIG. 1). Thereafter, the processor 10P registers the correction data related to the thermometer-type DA converter M_DAC among the generated correction amounts in the table THM_T, and registers the correction data related to the weighted binary-type DA converter S_DAC in the table BW_T. Accordingly, the test bit string and the correction amount are registered in the tables THM_T and BW_T of the bit string correction circuit 10BCT shown in FIG. 9, similarly to the table shown in FIG. 7.

The upper bit string U_Input is divided into the upper input bit string Inp_U for the thermometer-type DA converter M_DAC constituting the DA converter 10DAC(A) and the lower input bit string Inp_L for the weighted binary-type DA converter S_DAC constituting the DA converter 10DAC(A).

The table THM_T is searched by the divided upper input bit string Inp_U, and the table THM_T is searched by the divided lower input bit string Inp_L. The correction amount found by the search in each table is added by the adder ADD3 and supplied to the adder ADD4.

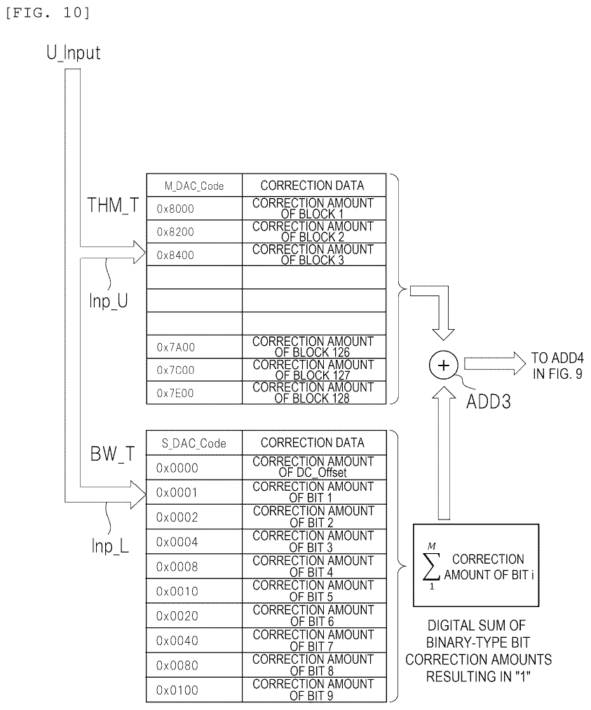

FIG. 10 shows a correction table according to Embodiment 2. FIG. 10 is similar to FIG. 8. A difference is that the upper bit string U_Input to be input to the DA converter DA converter 10DAC(A) to be corrected is used to search the tables THM_T and BW_T. In addition, FIG. 9 is also different from FIG. 8 in that the correction amount found by the search is added by the adder ADD3 and is further output to the adder ADD4.

As shown in FIG. 9, the adder ADD4 adds the lower bit string L_Input and the correction amount output from the bit string correction circuit 10BCT, so that the lower bit string corrected to correct the DA converter 10DAC(A) is input to the DA converter 10DAC(B). As a result, as in Embodiment 1, it is possible to reduce the number of test bit strings, increase a frequency of calibration, and reduce a large fluctuation in accuracy due to a fluctuation in the environmental temperature or the like. In addition, since the number of test bit strings is reduced, it is possible to prevent an increase in the size of the bit string correction circuit 10BCT.

In FIG. 9, the DA converter 10DAC(B) is also implemented by the segment-type DA converter. However, the DA converter 10DAC(B) may not be the segment-type DA converter.

### Embodiment 3

In the Embodiment 3, the input path of the AD converter 10AD shown in FIG. 1 is changed. That is, in FIG. 1, the output of the amplifier circuit AMP passes through the attenuator. The output is supplied to the AD converter 10AD. Accordingly, the analog value having a high voltage by an amplifier circuit 1403 is attenuated by an attenuator 1100 and supplied to an AD converter 1406, and it is possible to prevent the AD converter 1406 from being destroyed by a high voltage.

In the Embodiment 3, in the calibration period CAL, a correction amount obtained by integrating the input and output characteristic of the DA converter DAC(A) and the input and output characteristic of the amplifier circuit AMP is generated based on the test bit string, and the generated correction amount is registered in the bit string correction circuit 10BCT as a table.

Accordingly, the bit string correction circuit 10BCT corrects the bit string input to the DA converter DAC(A) by the correction amount considering the input and output characteristics of both the DA converter DAC(A) and the amplifier circuit AMP. As a result, accuracy of the analog value output from the amplifier circuit AMP can be improved. Of course, also in the case of using the two DA converters 10DAC(A) and 10DAC(B) as in Embodiment 2, the input and output characteristics of the amplifier circuit AMP may be considered in the same manner.

### Embodiment 4

In Embodiment 4, a charged particle beam device will be described as an example of a device having a DA converter.

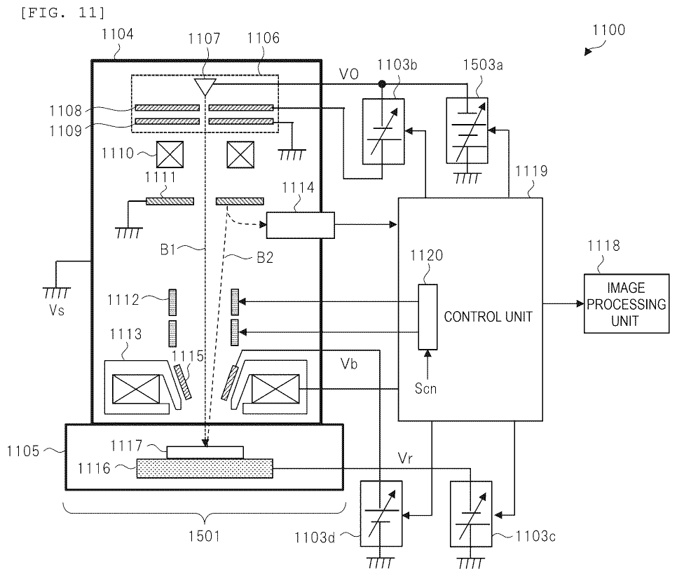

FIG. 11 is a schematic diagram showing a configuration of the charged particle beam device according to Embodiment 4. In the Embodiment 4, a case in which the charged particle beam device is an electron microscope device using an electron beam is taken as an example, and the charged particle beam device is not limited thereto, and may be, for example, an ion microscope device using an ion beam.

In FIG. 11, reference numeral 1100 denotes a charged particle beam device. The charged particle beam device 1100 schematically irradiates a sample 1117 with an electron beam (a charged particle beam) B1 emitted from an electron gun (a charged particle gun) 1106, and detects an emission amount of electrons (specifically, secondary electrons or reflected electrons) B2 emitted from the sample 1117 by a detector 1114.

The charged particle beam device 1100 shown in FIG. 11 includes a body portion 1101, a control unit 1119, a plurality of power supply circuits 1103a, 1103b, 1103c, and 1103d, and an image processing unit 1118. The body portion 1101 includes a housing 1104 and a sample chamber 1105. The housing 1104 accommodates the electron gun (charged particle gun) 1106, a condenser lens 1110, a reflection plate 1111, a deflector 1112, an objective lens 1113, the detector 1114, and a boost electrode 1115. The electron gun 1106 includes an electron source (charged particle source) 1107, an extraction electrode 1108, and an acceleration electrode 1109. The sample chamber 1105 accommodates a stage 1116 on which the sample 1117 is placed.

The housing 1104 is formed of a metal member and is connected to a ground power supply Vs. The power supply circuit 1103a generates a negative acceleration voltage V0 and supplies the voltage to the electron source 1107. The power supply circuit 1103b generates a positive extraction voltage based on the voltage (V0) of the electron source 1107 and supplies the extraction voltage to the extraction electrode 1108. The electron source 1107 emits the electron beam (charged particle beam) B1 by the extraction voltage. The acceleration electrode 1109 is connected to the ground power supply Vs. Accordingly, with reference to the electron source 1107, the positive acceleration voltage V0 is applied to the acceleration electrode 1109. The electron beam B1 emitted from the electron source 1107 is accelerated by the acceleration voltage V0.

The condenser lens 1110 focuses the electron beam B1 emitted from the electron gun 1106. The objective lens 1113 focuses the electron beam B1 so that the electron beam B1 becomes a minute spot on the sample 1117. At this time, the power supply circuit 1103d generates a positive boost voltage Vb and supplies the positive boost voltage Vb to the boost electrode 1115 installed near the condenser lens 1110. Accordingly, the electron beam B1 accelerated at the acceleration voltage V0 is further accelerated by the boost voltage Vb. Accordingly, it is possible to further increase a resolution of the electron beam B1.

The deflector 1112 is a magnetic field deflector or an electrostatic deflector, and deflects the electron beam B1 focused by the objective lens 1113 to scan the electron beam B1 (that is, a minute spot) emitted on the sample 1117. The power supply circuit 1103c generates a negative retarding voltage Vr and supplies the negative retarding voltage Vr to the stage 1116. Accordingly, the electron beam B1 passing through the objective lens 1113 is decelerated by the retarding voltage Vr. Accordingly, it is possible to reduce damage to the sample 1117.

Energy of, for example, several tens of kV is applied to the electron beam B1 by the acceleration voltage V0 and the boost voltage Vb. The retarding voltage Vr decreases the energy of the electron beam B1 to, for example, 1 kV or less. As described above, the energy of the electron beam B1 is appropriately determined by the power supply circuits 1103a to 1103d. However, the power supply circuit 1103d and the boost electrode 1115 may not be provided.

The sample 1117 emits the electrons (specifically, secondary electrons or reflected electrons) B2 according to the irradiation of the electron beam B1. The emitted electrons B2 are accelerated toward the electron source 1107 by the retarding voltage Vr and the boost voltage Vb and collide with the reflection plate 1111. Accordingly, the reflection plate 1111 emits secondary electrons. The detector 1114 detects an emission amount of the secondary electrons.

The control unit 1119 includes, for example, a wiring substrate (control substrate) on which various integrated circuits (ICs) including a processor are mounted. The control unit 1119 controls voltage values of the power supply circuits 1103a to 1103d. The control unit 1119 controls the deflector 1112, the objective lens 1113, and the like. Further, the control unit 1119 processes an output signal from the detector 1114 using a predetermined signal processing circuit. At this time, the control unit 1119 synchronizes a control signal to the deflector 1112 and an output signal from the detector 1114 to generate original data for generating a secondary electron image of a scanning area. The control unit 1119 does not necessarily have to be entirely mounted on one substrate. The control unit 1119 may include components included in a computer, for example, a volatile memory or a nonvolatile memory.

The image processing unit 1118 includes, for example, a computer such as a personal computer (PC) including various ICs including a processor. The image processing unit 1118 acquires the original data of the secondary electron image from the control unit 1119 and creates the secondary electron image based on the original data. The image processing unit 1118 displays the created secondary electron image on a display or the like. The secondary electron image is an image in which luminance varies depending on the emission amount of the secondary electrons at each position in the scanning area.

In the charged particle beam device 1100 according to Embodiment 4, the control unit 1119 includes: the pre-stage circuit 10FNT, the body circuit 10BDY, the AD converter 10AD, and the like described in Embodiments 1 to 3. Here, an example in which the body circuit 10BDY described in Embodiment 2 is used to control the deflector 1112 will be described, and the invention is not limited thereto, and the DA converter can be used to control various parts in the charged particle beam device 1100. It is needless to say that the DA converter used may be the one described in Embodiment 1 or 3.

In FIG. 11, reference numeral 1120 denotes a DA conversion circuit. The DA conversion circuit 1120 includes the pre-stage circuit 10FNT shown in FIG. 9, the body circuit 10BDY, and the amplifier circuit AMP (corresponding to the amplifier circuit AMP in FIG. 1) that amplifies an output of the body circuit 10BDY. A deflection signal Son is input to the DA conversion circuit 1120 as the input bit string Input, the deflection signal Son is converted into an analog value by the DA conversion circuit 1120, and the analog value is amplified by the amplifier circuit. The amplified deflection signal Son having an analog value is applied to the deflector 1112. The DA conversion circuit 1120 may include the AD converter 10AD and the processor 10P (FIG. 1) used for calibration. In this case, the processor 10P may also be included in the control unit 1119.

By linearly increasing (decreasing) the value of the deflection signal Scn with time, for example, the analog value applied to the deflector 1112 also linearly increases (decreases). Accordingly, a magnetic field or an electric field generated by the deflector 1112 also changes, and the electron beam B1 moves on the sample 1117.

When the linearity of the DA converter fluctuates due to, for example, the fluctuation of the environmental temperature, the magnetic field or the electric field generated by the deflector 1112 also fluctuates due to the fluctuation of the environmental temperature. As a result, a distance that the electron beam B1 moves on the sample 1117 changes, causing the image to expand or contract in the created secondary electron image. In particular, when an observation range is widened at a low resolution, the expansion and contraction of the image, which is dependent on the fluctuation of the environmental temperature, becomes remarkable.

As described above, by executing the calibration, the correction amount of the DA conversion circuit including the amplifier circuit is generated, the bit string input to the DA conversion circuit is corrected, and the linearity is improved. Moreover, according to the embodiment, since the calibration period CAL can be shortened, it is possible to reduce the shortening of an observation time of the sample by the charged particle beam device 1100 even if the frequency of the calibration is increased in order to cope with the fluctuation of the environmental temperature. Of course, the calibration may be executed a plurality of times without forming all the correction amounts in one time.

In FIG. 11, since the housing 1104 is viewed from a lateral direction, only one pair of deflectors 1112 is shown, but two pairs of deflectors 1112 are provided in the housing 1104 in order to move the electron beam B1 on the sample 1117 in the X direction and the Y direction (two substantially orthogonal directions). Since the DA conversion circuit 1120 supplies an analog signal to the pair of deflectors 1112 according to the deflection signal Scn, the control unit 1119 is provided with two pairs of the DA conversion circuits 1119 corresponding to the two pairs of deflectors. In this case, it is possible to prevent a test time from becoming long by simultaneously executing the calibration test on the two pairs of DA conversion circuits. Since the two pairs of DA conversion circuits are not necessarily considered to have the same characteristics, it is difficult for the two pairs of DA conversion circuits to share the correction data.

In Embodiment 4, the charged particle beam device is described as an example of the device having the DA converter, and the device 1 is not limited thereto.

In Embodiments 1 and 2, an example in which two tables THM_T and BW_T are used as the bit string correction circuit 10BCT is described, and the invention is not limited thereto. For example, the bit string correction circuit 10BCT may include one table (for convenience, U_TB). With reference to FIGS. 9 and 10 as an example, the bit string correction circuit 10BCT includes a table searched for by the upper bit string U_Input. In the calibration period CAL, a plurality of test bit strings corresponding to all codes of the upper bit string U_Input are supplied to the DA converter 10DAC(A). That is, 2\hat{ }^{N} test bit strings are prepared in advance with the number of bits N(=16 bits) of the upper bit string U_Input as an exponent. In the calibration period CAL, the processor 10P sequentially supplies the test bit string to the DA converter 10DAC(A), and the processor 10P compares the test bit string with a test result bit from the AD converter 10AD and generates a correction amount corresponding to the test bit string. The processor 10P registers the generated correction amount in the table U_TB. Accordingly, the table U_TB including the upper bit string U_Input corresponding to the test bit string and the correction amount is formed.

When the DA converter 10DAC(A) is actually used, the upper bit string U_Input is converted into an analog value by the DA converter 10DAC(A) and is supplied to the bit string correction circuit 10BCT. The table U_TB is searched by the upper bit string U_Input supplied to the bit string correction circuit 10BCT, converted into a correction amount, the correction amount is added to the lower bit string L_Input, converted into an analog value by the DA converter 10DAC(B), and added to the analog value from the DA converter 10DAC(A).

In this manner, by implementing the bit string correction circuit 10BCT, 2\hat{ }^{N} correction amounts are generated based on the 2\hat{ }^{N} test bit strings in the calibration period CAL, but the input bit string of the DA converter 10DAC(B) can be corrected in consideration of the input and output characteristics of the DA converter 10DAC(A) without considering the configuration of the DA converter 10DAC(A).

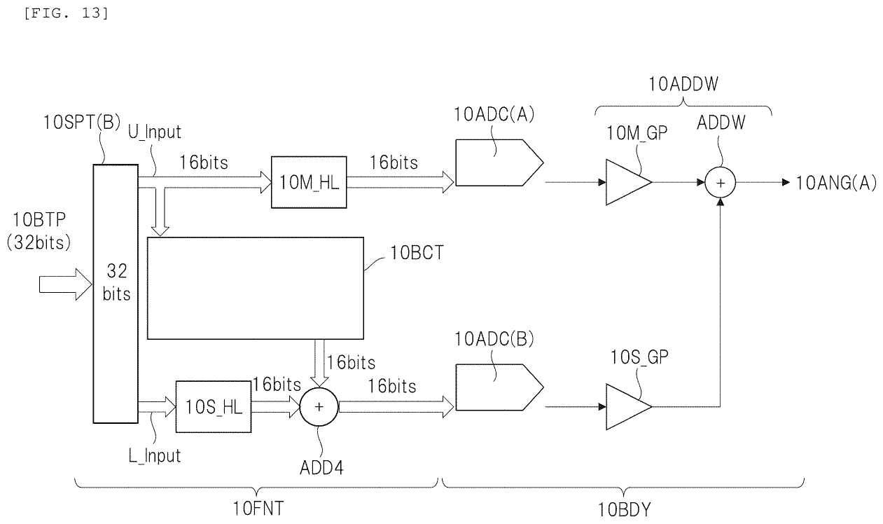

FIG. 13 is a diagram showing a modification of Embodiment 2 shown in FIG. 9, the modification including one table described above. Hereinafter, the modification is referred to as a modification of Embodiment 2. In the configuration of FIG. 13, the bit string correction circuit 10BCT including two tables as shown in FIG. 8 may be applied. In Embodiment 1, the bit string correction circuit 10BCT mainly adds and outputs the processor output bit string 10BTP using the adder ADD2 of FIG. 8. On the other hand, in Embodiment 2, such addition as the bit string correction circuit 10BCT is not performed as shown in FIG. 9. This is because the adder ADD4 performs a similar role. The description of Embodiment 2 may also be applied to the modification.

In Embodiments 1 to 4, in the segment-type DA converter, the example in which the main DA converter M_DAC that converts the upper input bit string Inp_U is implemented by the thermometer-type DA converter and the sub DA converter S_DAC that converts the lower input bit string Inp_L is implemented by the weighted binary-type DA converter is described, and the invention is not limited thereto. That is, the main DA converter M_DAC that converts the upper input bit string Inp_U may be implemented by a weighted binary-type DA converter, and the sub DA converter S_DAC that converts the lower input bit string Inp_L may be implemented by a thermometer-type DA converter.

From the viewpoint of binary format, endian, and encoding for communication, the bit string generated by the processor, the bit string output by the processor, the bit string input and output by the pre-stage circuit, the bit string input to the body circuit, the bit string input to the DA converter, and the bit string inside the DA converter may be the same or different. For example, when the DA conversion target value is generated in the processor, when the DA conversion target value is output from the processor 10P as the processor output bit string 10BTP, when the DA conversion target value corrected by the pre-stage circuit is output, and when the corrected DA conversion target value is input to the body circuit 10BDY or the DA converter 10DAC(A) may be different from each other (from the viewpoint of binary format, endian, and encoding for communication).

Although the invention made by the present inventors has been specifically described based on the embodiment, the invention is not limited to the embodiment, and it is needless to say that various modifications can be made without departing from the gist of the invention.

The following is described above in the present specification.

A device includes:
a processor configured to output a DA conversion target value;
a pre-stage circuit configured to receive the DA conversion target value from the processor, correct the DA conversion target value according to correction data, and output the corrected DA conversion target value;
a body circuit including one or more correction target DA converter elements and configured to perform DA conversion on the corrected DA conversion target value; and
an AD converter,
the correction target DA converter element is a hybrid-type DA converter element that outputs, from an output terminal, an analog value obtained by adding an analog value output by a first type circuit segment in charge of an upper order and an analog value output by a second type circuit segment in charge of a lower order, and
as a calibration test for creating or updating the correction data, the processor
   (A) acquires a plurality of test pairs each of which is a pair of a test input value and a test result value having the following characteristics:
      (A1) the test input value is a value input to the body circuit with or without correction as the DA conversion target value, and
      (A2) the test result value is a value obtained by performing AD conversion, by the AD converter, on an analog value output by inputting the test input value to the body circuit, and
   (B) updates the correction data based on the plurality of test pairs in (A), in which
the number of the test pairs acquired during a calibration test period being smaller than 2N, and
the N being the number of bits indicating a resolution of the correction target DA converter element.

In addition, it is described that the device may be as follows.

In the device, update of the correction data in (B) or generation of the test input value is performed based on the following for an input terminal bit string which is a bit string to which the correction target DA converter element is input at an input terminal:
a relation between 0 and 1 of a bit group included in the input terminal bit string, and the first type circuit segment and the second type circuit segment.

In addition, it is described that the device may be as follows.

In the device,
the correction target DA converter element has a division circuit that outputs an internal upper bit string of K bits and an internal lower bit string of M bits, based on an input value from an input terminal and a binary format assumed to be input by the element,
the internal upper bit string is input to the first type circuit segment,
the internal lower bit string is input to the second type circuit segment,
the calibration test includes a first type-oriented test for grasping a DA conversion characteristic of the first type circuit segment, and a second type-oriented test for grasping a DA conversion characteristic of the second type circuit segment,
a first type-oriented test input value to be used in the first type-oriented test is a value adjusted such that the internal lower bit string is a second fixed bit string after passing through the division circuit, and
a second type-oriented test input value to be used in the second type-oriented test is a value adjusted such that the internal upper bit string is a first fixed bit string after passing through the division circuit.

In addition, it is described that the device may be as follows.

In the device, the calibration test further includes an offset measurement test for outputting an analog value independent of a value of the internal upper bit string and a value of the internal lower bit string, and
a test input value to be used in the offset measurement test is a value adjusted such that the internal lower bit string is the second fixed bit string and the internal upper bit string is the first fixed bit string after passing through the division circuit.

In addition, it is described that the device may be as follows.

In the device,
the calibration test does not include a first reduction target test using a first reduction target test input value, and
the first reduction target test input value is a value adjusted to have the following characteristics after passing through the division circuit:
   the internal upper bit string is a value other than the first fixed bit string, and
   the internal lower bit string is a value other than the second fixed bit string.

In addition, it is described that the device may be as follows.

In the device,
the calibration test includes a first reduction target test using a first reduction target test input value, and
the first reduction target test input value is a value adjusted to have the following characteristics after passing through the division circuit:
   the internal upper bit string is a value other than the first fixed bit string,
   the internal lower bit string is a value other than the second fixed bit string, and
   the number of the test pairs to be used in the first reduction target test is 2^{N}−(2^{K}+2^{M}+1).

In addition, it is described that the device may be as follows.

In the device,
the correction target DA converter element has a division circuit that outputs an internal upper bit string of K bits and an internal lower bit string of M bits, based on an input value from an input terminal and a binary format assumed to be input by the element,
the internal upper bit string is input to the first type circuit segment,
the internal lower bit string is input to the second type circuit segment,
the first type circuit segment includes a plurality of first type circuits and a selector circuit,
the selector circuit is a circuit that selects one of the first type circuits according to the internal upper bit string, outputs an active signal to the selected first type circuit, and outputs an inactive signal to the non-selected first type circuit,
each of the first type circuits includes a circuit element for outputting an analog value according to a weight of the internal upper bit string and the active signal or the inactive signal,
the second type circuit segment is a segment that has a second type circuit corresponding to each of bits of the internal lower bit string, and adds analog values output by each of the second type circuits to obtain an output value as the segment, and
the first type circuit includes a circuit element for outputting the analog value according to the weight of the bit and an active/inactive state indicated by the bit.

In addition, it is described that the device may be as follows.

In the device, update of the correction data in (B) or generation of the test input value is performed based on the following for an input terminal bit string which is a bit string to which the correction target DA converter element is input at an input terminal:
a relation between 0/1 of a bit group included in the input terminal bit string and the active/inactive state of the plurality of first type circuits and the plurality of second type circuits.

In addition, it is described that the device may be as follows.

In the device, the number of the test pairs acquired during the calibration test period is equal to or greater than a sum of the number of the first type circuits and the number of the second type circuits.

In addition, it is described that the device may be as follows.

In the device, the first type circuit segment is a thermometer-type circuit segment, and
the second type circuit segment binary-type or ladder-type circuit segment.

In addition, it is described that the device may be as follows.

In the device, the pre-stage circuit stores, as the correction data, a first table for managing a correction amount derived from the first type circuit segment and a second table for managing a correction amount derived from the second type circuit segment.

In addition, it is described that the device may be as follows.

In the device, the body circuit is a circuit that performs DA conversion of N+1 bits or more by jointly using a sub DA converter element in charge of a lower order in addition to the correction target DA converter element in charge of an upper order,
the pre-stage circuit includes
   a division circuit or a division wiring that receives the DA conversion target value and divides and outputs an upper DA conversion target value and a lower DA conversion target value,
   a correction circuit that outputs a correction amount obtained based on the upper DA conversion target value and the correction data, and
   an addition circuit that adds the correction amount and the lower DA conversion target value and outputs the corrected lower DA conversion target value,
the correction target DA converter element sets the upper DA conversion target value as a conversion target,
the sub DA converter element sets the corrected lower DA conversion target value as a conversion target, and
the body circuit includes a weighted addition circuit that performs weighted addition of an analog value output by the correction target DA converter element and an analog value output by the sub DA converter element to output an analog value.

In addition, it is described that the device may be as follows.

In the device, a body circuit includes a wiring that outputs the analog value output by the weighted addition circuit as the body output analog value.

In addition, it is described that the device may be as follows.

In the device, the body circuit includes
an amplifier circuit that amplifies the analog value output by the weighted addition circuit, and
a wiring that outputs an analog value amplified by the amplifier circuit as thea body output analog value.

In addition, it is described that the device may be as follows.

In the device, the pre-stage circuit includes
a correction circuit that receives a processor output bit string and outputs a correction amount bit string based on the correction data, and
an addition circuit that adds the correction amount bit string and the processor output bit string and outputs a body input bit string.

In addition, it is described that the device may be as follows.

In the device, the pre-stage circuit includes a correction circuit that receives a processor output bit string and outputs a body input bit string based on the correction data.

In addition, it is described that the device may be as follows.

A charged particle beam device includes:
a charged particle source configured to generate a charged particle beam;
a deflector configured to deflect the charged particle beam; and
the above-described device as a controller configured to control the deflector.

In the present specification, the following is described.

A device includes at least:
a body circuit including one or more DA converter elements, and configured to convert a body input bit string, which is a received bit string, into a body output analog value, which is an analog value, and output the body output analog value;
a processor configured to output a processor output bit string;
a pre-stage circuit configured to receive the processor output bit string and outputs the body input bit string; and
an AD converter,
the pre-stage circuit corrects the processor output bit string based on correction data and outputs the body input bit string,
the body circuit includes an amplifier circuit that amplifies an analog value output by the DA converter element and that outputs the amplified analog value as the body output analog value, and
the processor
   (A) acquires a plurality of pairs of a test bit string and a test result bit string having the following characteristics:
      (A1) the test bit string is the processor output bit string or the body input bit string for a calibration test,
      (A2) the test result bit string is acquired by converting the body output analog value by the AD converter, and
   (B) updates the correction data based on the plurality of pairs in (A).

### REFERENCE SIGNS LIST

1: device
10AD: AD converter
10ADDW: weighted addition circuit
10BCT: bit string correction circuit
10BDY: body circuit
10DAC(A), 10DAC(B): DA converter
10FNT: pre-stage circuit
10P: processor
10SPT(A), 10SPT(B): division circuit
1100: charged particle beam device
Inp_L: lower input bit string
Inp_U: upper input bit string
L_Input: lower bit string
M_DAC: main DA converter
S_DAC: sub DA converter
U_Input: upper bit string

1. A device comprising at least:
a processor configured to output a DA conversion target value;
a pre-stage circuit configured to receive the DA conversion target value from the processor, correct the DA conversion target value according to correction data, and output the corrected DA conversion target value;
a body circuit including one or more correction target DA converter elements and configured to perform DA conversion on the corrected DA conversion target value; and
an AD converter, wherein
the correction target DA converter element is a hybrid-type DA converter element that outputs, from an output terminal, an analog value obtained by adding an analog value output by a first type circuit segment in charge of an upper order and an analog value output by a second type circuit segment in charge of a lower order, and
as a calibration test for creating or updating the correction data, the processor
(A) acquires a plurality of test pairs each of which is a pair of a test input value and a test result value having the following characteristics:
(A1) the test input value is a value input to the body circuit with or without correction as the DA conversion target value, and
(A2) the test result value is a value obtained by performing AD conversion, by the AD converter, on an analog value output by inputting the test input value to the body circuit, and
(B) updates the correction data based on the plurality of test pairs in (A), wherein
the number of the test pairs acquired during a calibration test period being smaller than 2^{N}, and
the N being the number of bits indicating a resolution of the correction target DA converter element.

2. The device according to claim 1, wherein
update of the correction data in (B) or generation of the test input value is performed based on the following for an input terminal bit string which is a bit string to which the correction target DA converter element is input at an input terminal:
a relation between 0 and 1 of a bit group included in the input terminal bit string, and the first type circuit segment and the second type circuit segment.

3. The device according to claim 1, wherein
the correction target DA converter element has a division circuit that outputs an internal upper bit string of K bits and an internal lower bit string of M bits, based on an input value from an input terminal and a binary format assumed to be input by the element,
the internal upper bit string is input to the first type circuit segment,
the internal lower bit string is input to the second type circuit segment,
the calibration test includes a first type-oriented test for grasping a DA conversion characteristic of the first type circuit segment, and a second type-oriented test for grasping a DA conversion characteristic of the second type circuit segment,
a first type-oriented test input value to be used in the first type-oriented test is a value adjusted such that the internal lower bit string is a second fixed bit string after passing through the division circuit, and
a second type-oriented test input value to be used in the second type-oriented test is a value adjusted such that the internal upper bit string is a first fixed bit string after passing through the division circuit.

4. The device according to claim 3, wherein
the calibration test further includes an offset measurement test for outputting an analog value independent of a value of the internal upper bit string and a value of the internal lower bit string, and
a test input value to be used in the offset measurement test is a value adjusted such that the internal lower bit string is the second fixed bit string and the internal upper bit string is the first fixed bit string after passing through the division circuit.

5. The device according to claim 4, wherein
the calibration test does not include a first reduction target test using a first reduction target test input value, and
the first reduction target test input value is a value adjusted to have the following characteristics after passing through the division circuit:
the internal upper bit string is a value other than the first fixed bit string, and
the internal lower bit string is a value other than the second fixed bit string.

6. The device according to claim 4, wherein
the calibration test includes a first reduction target test using a first reduction target test input value, and
the first reduction target test input value is a value adjusted to have the following characteristics after passing through the division circuit:
the internal upper bit string is a value other than the first fixed bit string,
the internal lower bit string is a value other than the second fixed bit string, and
the number of the test pairs to be used in the first reduction target test is 2^{N}−(2^{K}+2^{M}+1).

7. The device according to claim 1, wherein
the correction target DA converter element has a division circuit that outputs an internal upper bit string of K bits and an internal lower bit string of M bits, based on an input value from an input terminal and a binary format assumed to be input by the element,
the internal upper bit string is input to the first type circuit segment,
the internal lower bit string is input to the second type circuit segment,
the first type circuit segment includes a plurality of first type circuits and a selector circuit,
the selector circuit is a circuit that selects one of the first type circuits according to the internal upper bit string, outputs an active signal to the selected first type circuit, and outputs an inactive signal to the non-selected first type circuit,
each of the first type circuits includes a circuit element for outputting an analog value according to a weight of the internal upper bit string and the active signal or the inactive signal,
the second type circuit segment is a segment that has a second type circuit corresponding to each of bits of the internal lower bit string, and adds analog values output by each of the second type circuits to obtain an output value as the segment, and
the first type circuit includes a circuit element for outputting the analog value according to the weight of the bit and an active/inactive state indicated by the bit.

8. The device according to claim 7, wherein
update of the correction data in (B) or generation of the test input value is performed based on the following for an input terminal bit string which is a bit string to which the correction target DA converter element is input at an input terminal:
a relation between 0/1 of a bit group included in the input terminal bit string and the active/inactive state of the plurality of first type circuits and the plurality of second type circuits.

9. The device according to claim 8, wherein
the number of the test pairs acquired during the calibration test period is equal to or greater than a sum of the number of the first type circuits and the number of the second type circuits.

10. The device according to claim 1, wherein
the first type circuit segment is a thermometer-type circuit segment, and
the second type circuit segment is a binary-type or ladder-type circuit segment.

11. The device according to claim 1, wherein
the pre-stage circuit stores, as the correction data, a first table for managing a correction amount derived from the first type circuit segment and a second table for managing a correction amount derived from the second type circuit segment.

12. The device according to claim 1, wherein
the body circuit is a circuit that performs DA conversion of N+1 bits or more by using a sub DA converter element in charge of a lower order in addition to the correction target DA converter element in charge of an upper order,
the pre-stage circuit includes
a division circuit or a division wiring that receives the DA conversion target value and divides and outputs an upper DA conversion target value and a lower DA conversion target value,
a correction circuit that outputs a correction amount obtained based on the upper DA conversion target value and the correction data, and
an addition circuit that adds the correction amount and the lower DA conversion target value and outputs the corrected lower DA conversion target value,
the correction target DA converter element sets the upper DA conversion target value as a conversion target,
the sub DA converter element sets the corrected lower DA conversion target value as a conversion target, and
the body circuit includes a weighted addition circuit that performs weighted addition of an analog value output by the correction target DA converter element and an analog value output by the sub DA converter element to output an analog value.

13. The device according to claim 9, wherein
the body circuit includes a wiring that outputs the analog value output by the weighted addition circuit as a body output analog value.

14. The device according to claim 9, wherein
the body circuit includes
an amplifier circuit that amplifies the analog value output by the weighted addition circuit, and
a wiring that outputs an analog value amplified by the amplifier circuit as a body output analog value.

15. The device according to claim 1, wherein
the pre-stage circuit includes
a correction circuit that receives a processor output bit string and outputs a correction amount bit string based on the correction data, and
an addition circuit that adds the correction amount bit string and the processor output bit string and outputs a body input bit string.

16. The device according to claim 1, wherein
the pre-stage circuit includes a correction circuit that receives a processor output bit string and outputs a body input bit string based on the correction data.

17. A charged particle beam device comprising:
a charged particle source configured to generate a charged particle beam;
a deflector configured to deflect the charged particle beam; and
the device according to claim 1 as a controller configured to control the deflector.

18. A device comprising at least:
a body circuit including one or more DA converter elements, and configured to convert a body input bit string, which is a received bit string, into a body output analog value, which is an analog value, and output the body output analog value;
a processor configured to output a processor output bit string;
a pre-stage circuit configured to receive the processor output bit string and outputs the body input bit string; and
an AD converter, wherein
the pre-stage circuit corrects the processor output bit string based on correction data and outputs the body input bit string,
the body circuit includes an amplifier circuit that amplifies an analog value output by the DA converter element and that outputs the amplified analog value as the body output analog value, and
the processor
(A) acquires a plurality of pairs of a test bit string and a test result bit string having the following characteristics:
(A1) the test bit string is the processor output bit string or the body input bit string for a calibration test,
(A2) the test result bit string is acquired by converting the body output analog value by the AD converter, and
(B) updates the correction data based on the plurality of pairs in (A).
